(19) United States
(12) Patent Application Publication
(10) Pub. No.: US 2025/0344499 A1
(43) Pub. Date: Nov. 6, 2025

(54) STACKED TRANSISTOR CHANNEL REGIONS AND METHODS OF FORMING THE SAME

(71) Applicant: Taiwan Semiconductor Manufacturing Co., Ltd., Hsinchu (TW)

(72) Inventors: Yu-Wei Lu, Taipei City (TW); Kenichi Sano, Hsinchu (TW); Tze-Chung Lin, Hsinchu (TW); Fang-Wei Lee, Hsinchu (TW); Chia-Chien Kuang, Taipei City (TW); Yi-Chen Lo, Zhubei City (TW); Fo-Ju Lin, Keelung City (TW); Li-Te Lin, Hsinchu (TW); Pinyen Lin, Rochester, NY (US)

(21) Appl. No.: 19/269,909

(22) Filed: Jul. 15, 2025

Related U.S. Application Data
(63) Continuation of application No. 18/361,152, filed on Jul. 28, 2023.

(51) Int. Cl. H10D 84/85; H10D 30/43; H10D 30/67; H10D 62/10; H10D 64/23; H10D 84/01; H10D 84/03

(52) U.S. Cl. CPC H10D 84/85; H10D 30/43; H10D 30/6735; H10D 30/6757; H10D 62/121; H10D 64/258; H10D 84/0172; H10D 84/038

(57) ABSTRACT

In an embodiment, a device includes: lower semiconductor nanostructures including a first semiconductor material; a lower epitaxial source/drain region adjacent the lower semiconductor nanostructures, the lower epitaxial source/drain region having a first conductivity type; upper semiconductor nanostructures including a second semiconductor material, the second semiconductor material different from the first semiconductor material; and an upper epitaxial source/drain region adjacent the upper semiconductor nanostructures, the upper epitaxial source/drain region having a second conductivity type, the second conductivity type being opposite the first conductivity type.

### CROSS-REFERENCE TO RELATED APPLICATIONS

This application is a continuation of U.S. patent application Ser. No. 18/361,152, filed on Jul. 28, 2023, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example schematic of a stacked transistor, such as a complementary field-effect transistor (CFET), in a three-dimensional view, in accordance with some embodiments.

FIGS. 2-25 are views of intermediate stages in the manufacturing of CFETs, in accordance with some embodiments.

FIG. 26 is a view of CFETs, in accordance with some embodiments.

FIGS. 27-38 are views of intermediate stages in the manufacturing of CFETs, in accordance with some other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, CFETs include lower nanostructure field-effect transistors (nanostructure-FETs) and upper nanostructure-FETs. The lower nanostructure-FETs include channel regions formed of a first semiconductor material and the upper nanostructure-FETs include channel regions formed of a second semiconductor material. The first and second semiconductor materials are different, which allows the lower and upper nanostructure-FETs to have a different threshold voltages.

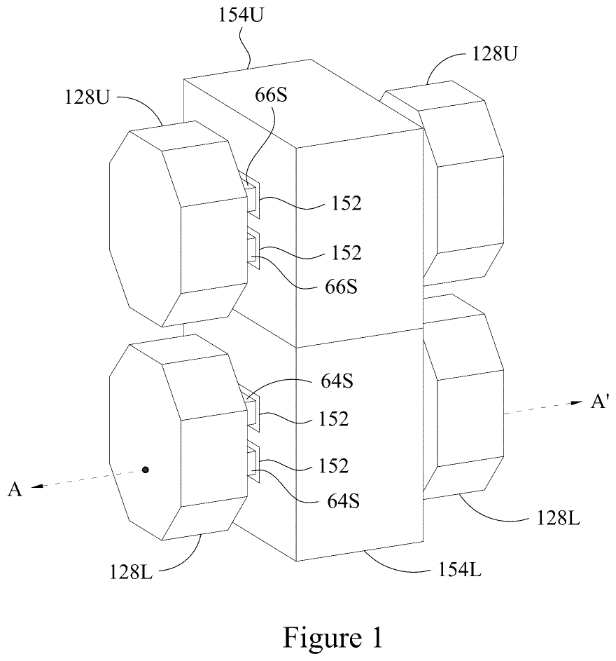

FIG. 1 illustrates an example schematic of a stacked transistor, such as a complementary field-effect transistor (CFET), in accordance with some embodiments. FIG. 1 is a three-dimensional view, where some features of the CFETs are omitted for illustration clarity.

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 64S, 66S (including lower semiconductor nanostructures 64S and upper semiconductor nanostructures 66S), where the semiconductor nanostructures 64S, 66S act as channel regions for the nanostructure-FETs. The semiconductor nanostructures 64S, 66S may be nanosheets, nanowires, or the like. The lower semiconductor nanostructures 64S are for a lower nanostructure-FET and the upper semiconductor nanostructures 66S are for an upper nanostructure-FET. A channel isolation material (not explicitly illustrated in FIG. 1; see FIG. 25) may be used to separate and electrically isolate the upper semiconductor nanostructures 66S from the lower semiconductor nanostructures 64S.

Gate dielectrics 152 are along top surfaces, sidewalls, and bottom surfaces of the semiconductor nanostructures 64S, 66S. Gate electrodes 154 (including a lower gate electrode 154L and an upper gate electrode 154U) are over the gate dielectrics 152 and around the semiconductor nanostructures 64S, 66S. Source/drain regions 128 (including lower epitaxial source/drain regions 128L and upper epitaxial source/drain regions 128U) are disposed at opposing sides of the gate dielectrics 152 and the gate electrodes 154. Source/drain region(s) 128 may refer to a source or a drain, individually or collectively dependent upon the context. Isolation features may be formed to separate desired ones of the source/drain regions 128 and/or desired ones of the gate electrodes 154. For example, a lower gate electrode 154L may optionally be separated from an upper gate electrode 154U. Alternatively, a lower gate electrode 154L may be coupled to an upper gate electrode 154U. Further, the upper epitaxial source/drain regions 128U may be separated from lower epitaxial source/drain regions 128L by one or more dielectric layers (not explicitly illustrated in FIG. 1, see FIG. 25). The isolation features between channel regions, gates, and source/drain regions allow for vertically stacked transistors, thereby improving device density. Because of the vertically stacked nature of CFETs, the schematic may also be referred to as stacked transistors or folding transistors.

FIG. 1 further illustrates a reference cross-section that is used in later figures. Cross-section A-A′ is parallel to a longitudinal axis of the semiconductor nanostructures 64S, 66S of a CFET and in a direction of, for example, a current flow between the source/drain regions 128 of the CFET. Subsequent figures refer to this reference cross-section for clarity.

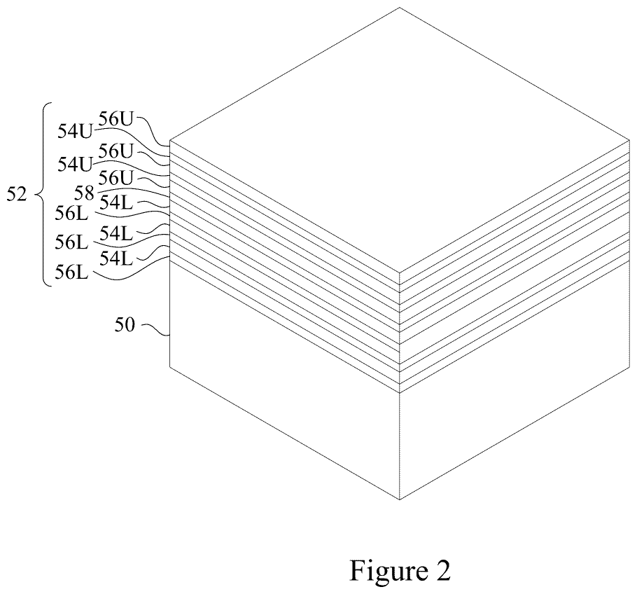

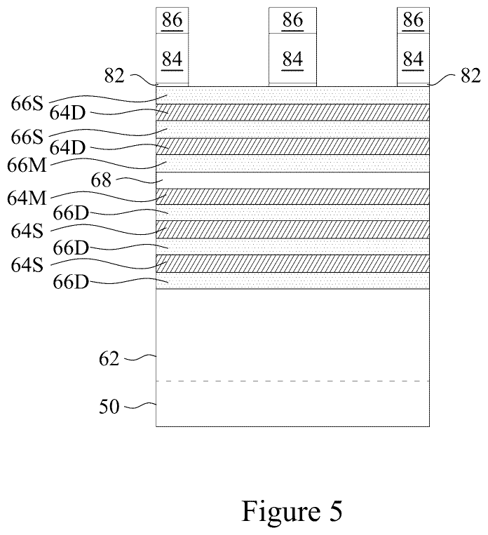

FIGS. 2-25 are views of intermediate stages in the manufacturing of CFETs, in accordance with some embodiments. FIGS. 2, 3, and 4 are three-dimensional views showing a similar three-dimensional view as FIG. 1. FIGS. 5, 6, 7, 8, 9, 10, 11, 12, 13, 14, 15, 16, 17, 18, 19, 20, 21, 22, 23, 24, and 25 illustrate cross-sectional views along a similar cross-section as reference cross-section A-A′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating first semiconductor layers 54 (including lower first semiconductor layers 54L and upper first semiconductor layers 54U) and second semiconductor layers 56 (including lower second semiconductor layers 56L and upper second semiconductor layers 56U). Additionally, the multi-layer stack 52 includes a dummy semiconductor layer 58. The lower first semiconductor layers 54L and the lower second semiconductor layers 56L are disposed below the dummy semiconductor layer 58. The upper first semiconductor layers 54U and the upper second semiconductor layers 56U are disposed above the dummy semiconductor layer 58. As subsequently described in greater detail, various one of the first semiconductor layers 54 and the second semiconductor layers 56 will be removed/patterned to form channel regions of CFETs. Specifically, the lower second semiconductor layers 56L will be removed and the lower first semiconductor layers 54L will be patterned to form channel regions of the lower nanostructure-FETs of the CFETs, and the upper first semiconductor layers 54U will be removed and the upper second semiconductor layers 56U will be patterned to form channel regions of the upper nanostructure-FETs of the CFETs.

The multi-layer stack 52 is illustrated as including a specific number of the first semiconductor layers 54 and a specific number of the second semiconductor layers 56. It should be appreciated that the multi-layer stack 52 may include any number of the first semiconductor layers 54 and the second semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first semiconductor layers 54 are formed of a first semiconductor material suitable for the first device type of the lower nanostructure-FETs. The second semiconductor layers 56 are formed of a second semiconductor material suitable for the second device type of the upper nanostructure-FETs. Acceptable semiconductor materials for n-type devices may include silicon, silicon carbide, or the like. Acceptable semiconductor materials for p-type devices may include germanium, silicon-germanium, or the like. When silicon-germanium is used for p-type devices, it may be silicon-germanium with a low germanium concentration, such as a germanium concentration in the range of 15% to 25%. The first and second semiconductor materials have a high etching selectivity to one another. As such, the second semiconductor layers 56 of the second semiconductor material may be removed without significantly removing the first semiconductor layers 54 of the first semiconductor material, thereby allowing the first semiconductor layers 54 to be patterned to form channel regions of the lower nanostructure-FETs. Similarly, the first semiconductor layers 54 of the first semiconductor material may be removed without significantly removing the second semiconductor layers 56 of the second semiconductor material, thereby allowing the second semiconductor layers 56 to be patterned to form channel regions of the upper nanostructure-FETs. The dummy semiconductor layer 58 is formed of a third semiconductor material having a high etching selectivity to each of the first and second semiconductor materials, such as silicon-germanium with a high germanium concentration, such as a germanium concentration in the range of 35% to 45%. As such, the dummy semiconductor layer 58 of the third semiconductor material may be removed without significantly removing the first semiconductor layers 54 or the second semiconductor layers 56 in subsequent processing.

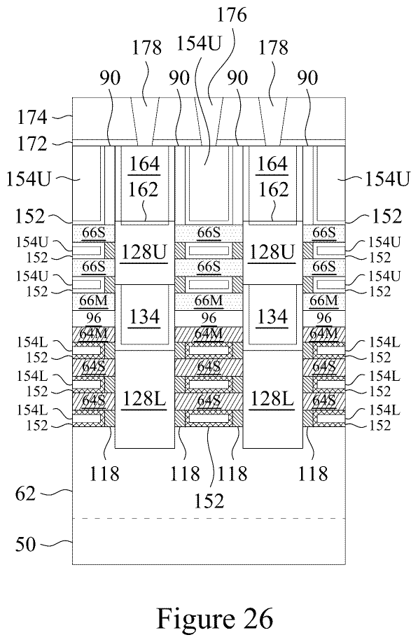

In this embodiment, the first semiconductor material of the first semiconductor layers 54 is a semiconductor material for p-type devices, and the second semiconductor material of the second semiconductor layers 56 is a semiconductor material for n-type devices. Accordingly, the multi-layer stack 52 has a bottommost semiconductor layer suitable for n-type devices. In another embodiment (subsequently described for FIG. 26), the first semiconductor material of the first semiconductor layers 54 is a semiconductor material for n-type devices, and the second semiconductor material of the second semiconductor layers 56 is a semiconductor material for p-type devices. Accordingly, the multi-layer stack 52 has a bottommost semiconductor layer suitable for p-type devices.

Some layers of the multi-layer stack 52 may be thicker than other layers of the multi-layer stack 52. The thickness of the dummy semiconductor layer 58 may be different (e.g., greater or less) than the thickness of each of the first semiconductor layers 54 and the second semiconductor layers 56. Specifically, the dummy semiconductor layer 58 may have a large thickness, such as a greater thickness than each of the first semiconductor layers 54 and the second semiconductor layers 56. Forming the dummy semiconductor layer 58 to a large thickness allows the dummy semiconductor layer 58 to be more easily removed in subsequently processing.

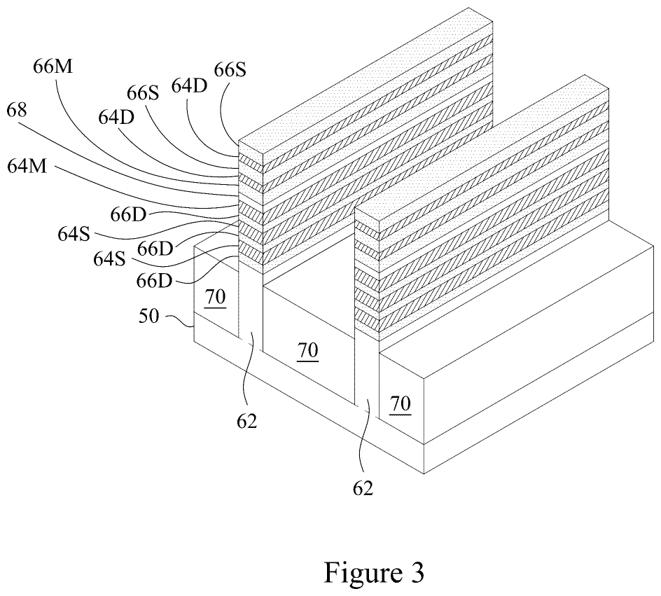

In FIG. 3, semiconductor fins 62 are formed in the substrate 50 and nanostructures 64, 66 (including lower semiconductor nanostructures 64S, lower dummy nanostructures 66D, first middle nanostructures 64M, second middle nanostructures 66M, upper semiconductor nanostructures 66S, upper dummy nanostructures 64D, and dummy nanostructures 68) are formed in the multi-layer stack 52. In some embodiments, the nanostructures 64, 66 and the semiconductor fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the lower semiconductor nanostructures 64S from some of the lower first semiconductor layers 54L, the lower dummy nanostructures 66D from the lower second semiconductor layers 56L, the first middle nanostructures 64M from some of the lower first semiconductor layers 54L, the upper semiconductor nanostructures 66S from some of the upper second semiconductor layers 56U, the upper dummy nanostructures 64D from the upper first semiconductor layers 54U, the second middle nanostructures 66M from some of the upper second semiconductor layers 56U, and the dummy nanostructures 68 from the dummy semiconductor layer 58. The lower semiconductor nanostructures 64S, the first middle nanostructures 64M, and the upper dummy nanostructures 64D may further be collectively referred to as the first nanostructures 64. The lower dummy nanostructures 66D, the second middle nanostructures 66M, and the upper semiconductor nanostructures 66S may further be collectively referred to as the second nanostructures 66.

As subsequently described in greater detail, various one of the nanostructures 64, 66 will be removed to form channel regions of CFETs. Specifically, the lower semiconductor nanostructures 64S will act as channel regions for lower nanostructure-FETs of the CFETs. Additionally, the upper semiconductor nanostructures 66S will act as channel regions for upper nanostructure-FETs of the CFETs.

The first middle nanostructures 64M and the second middle nanostructures 66M are the nanostructures that are directly above/below (e.g., in contact with) the dummy nanostructures 68. Depending on the heights of subsequently formed source/drain regions, the first middle nanostructures 64M and the second middle nanostructures 66M may or may not adjoin any source/drain regions and may or may not act as functional channel regions for the CFETs. The dummy nanostructures 68 will be subsequently replaced with isolation structures. The isolation structures, the first middle nanostructures 64M, and the second middle nanostructures 66M may define boundaries of the lower nanostructure-FETs and the upper nanostructure-FETs.

The semiconductor fins 62, the nanostructures 64, 66, and the dummy nanostructures 68 may be patterned by any suitable method. For example, the semiconductor fins 62, the nanostructures 64, 66, and the dummy nanostructures 68 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the semiconductor fins 62, the nanostructures 64, 66, and the dummy nanostructures 68. In some embodiments, a mask (or other layer) may remain on the nanostructures 64, 66.

Although each of the semiconductor fins 62, the nanostructures 64, 66, and the dummy nanostructures 68 are illustrated as having a constant width throughout, in other embodiments, the semiconductor fins 62, the nanostructures 64, 66, and/or the dummy nanostructures 68 may have tapered sidewalls such that a width of each of the semiconductor fins 62, the nanostructures 64, 66, and/or the dummy nanostructures 68 continuously increases in a direction towards the substrate 50. In such embodiments, each of the nanostructures 64, 66 and the dummy nanostructures 68 may have a different width and be trapezoidal in shape.

Further, isolation regions 70 are formed over the substrate 50 and between adjacent semiconductor fins 62. The isolation regions 70 may include a liner and a fill material over the liner. Each of the liner and the fill material may include a dielectric material such as an oxide (e.g., silicon oxide), a nitride (e.g., silicon nitride), the like, or a combination thereof. The formation of the isolation regions 70 may include depositing the dielectric material(s), and performing a planarization process such as a chemical mechanical polish (CMP) process, a mechanical polishing process, or the like to remove excess portions of the dielectric material(s), such as portions over the nanostructures 64, 66. The deposition processes may include ALD, high-density plasma chemical vapor deposition (HDP-CVD), flowable chemical vapor deposition (FCVD), the like, or a combination thereof. In some embodiments, the isolation regions 70 include silicon oxide formed by an FCVD process, followed by an anneal process. Then, the dielectric material(s) are recessed to define the isolation regions 70. The dielectric material(s) maybe recessed such that upper portions of the semiconductor fins 62, the nanostructures 64, 66, and the dummy nanostructures 68 extend higher than the isolation regions 70.

The previously described process is just one example of how the semiconductor fins 62 and the nanostructures 64, 66 may be formed. In some embodiments, the semiconductor fins 62, the nanostructures 64, 66, and/or the dummy nanostructures 68 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the semiconductor fins 62, the nanostructures 64, 66, and/or the dummy nanostructures 68. The epitaxial structures may comprise the previously described alternating semiconductor materials, such as the first semiconductor material, the second semiconductor material, and the third semiconductor material. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the nanostructures 64, 66 and/or the semiconductor fins 62. For example, an n-type impurity implant and/or a p-type impurity implant may be performed, or the semiconductor materials may be in situ doped during growth. The n-type impurities may be phosphorus, arsenic, antimony, or the like at a concentration in a range from 10¹⁷ atoms/cm³ to 10¹⁹ atoms/cm³. The p-type impurities may be boron, boron fluoride, indium, or the like at a concentration in a range from 10¹⁷ atoms/cm³ to 10¹⁹ atoms/cm³. The wells in the lower semiconductor nanostructures 64S have a conductivity type opposite from a conductivity type of lower epitaxial source/drain regions that will be subsequently formed adjacent the lower semiconductor nanostructures 64S. The wells in the upper semiconductor nanostructures 66S have a conductivity type opposite from a conductivity type of upper epitaxial source/drain regions that will be subsequently formed adjacent the upper semiconductor nanostructures 66S.

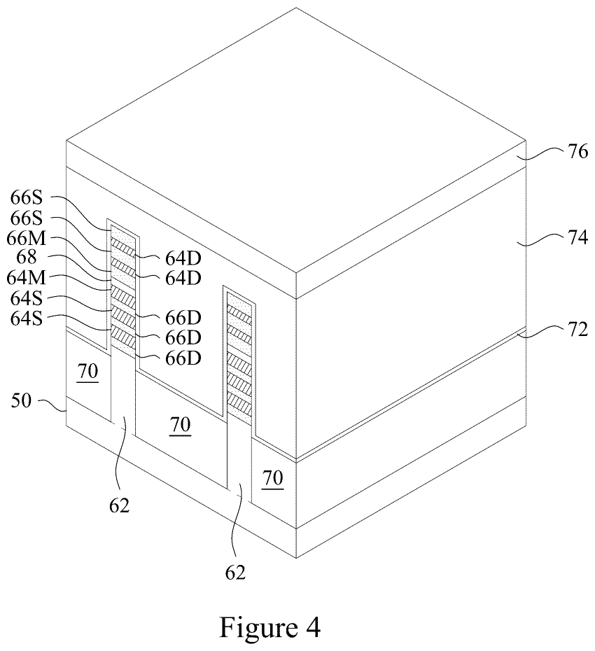

In FIG. 4, a dummy dielectric layer 72 is formed on the semiconductor fins 62, the nanostructures 64, 66, and/or the dummy nanostructures 68. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the semiconductor fins 62, the nanostructures 64, 66, and/or the dummy nanostructures 68.

In FIG. 5, the mask layer 76 may be patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective semiconductor fins 62. The masks 86 can optionally be removed after patterning, such as by any acceptable etching technique.

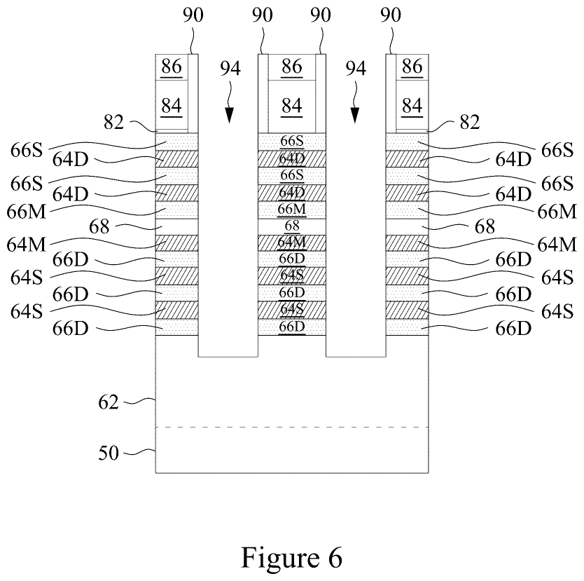

In FIG. 6, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). In some embodiments, the dielectric material(s), when etched, may also have portions left on the sidewalls of the semiconductor fins 62, the nanostructures 64, 66, and/or the dummy nanostructures 68.

Further, implants for lightly doped source/drain (LDD) regions (not separately illustrated) may be performed. The LDD implants may be performed before the gate spacers 90 are formed. Appropriate type impurities may be implanted into the nanostructures 64, 66 to a desired depth. The LDD regions may have a same conductivity type as a conductivity type of source/drain regions that will be subsequently formed adjacent the lower semiconductor nanostructures 64S and the upper semiconductor nanostructures 66S. Additionally, the LDD regions in the lower semiconductor nanostructures 64S may have a conductivity type opposite from a conductivity type of the LDD regions in the upper semiconductor nanostructures 66S. In some embodiments, the lower semiconductor nanostructures 64S have p-type LDD regions and the upper semiconductor nanostructures 66S have n-type LDD regions. In some embodiments, the lower semiconductor nanostructures 64S have n-type LDD regions and the upper semiconductor nanostructures 66S have p-type LDD regions. The n-type impurities may be the any of the n-type impurities previously discussed, and the p-type impurities may be the any of the p-type impurities previously discussed. The lightly doped source/drain regions may have a concentration of impurities in a range from 10¹⁷ atoms/cm³ to 10²⁰ atoms/cm³. An anneal may be used to repair implant damage and to activate the implanted impurities. In some embodiments, the grown materials of the nanostructures 64, 66 may be in situ doped during growth, which may obviate the implantations, although in situ and implantation doping may be used together.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like.

Source/drain recesses 94 are formed in the semiconductor fins 62, the nanostructures 64, 66, the dummy nanostructures 68, and the substrate 50. Epitaxial source/drain regions will be subsequently formed in the source/drain recesses 94. The source/drain recesses 94 may extend through the nanostructures 64, 66 and into the substrate 50. The semiconductor fins 62 may be etched such that bottom surfaces of the source/drain recesses 94 are disposed above, below, or level with the top surfaces of the isolation regions 70. In the illustrated example, the top surfaces of the isolation regions 70 are above the bottom surfaces of the source/drain recesses 94. The source/drain recesses 94 may be formed by etching the semiconductor fins 62, the nanostructures 64, 66, the dummy nanostructures 68, and the substrate 50 using anisotropic etching processes, such as RIE, NBE, or the like. The gate spacers 90 and the dummy gates 84 mask portions of the semiconductor fins 62, the nanostructures 64, 66, the dummy nanostructures 68, and the substrate 50 during the etching processes used to form the source/drain recesses 94. A single etch process or multiple etch processes may be used to etch each layer of the nanostructures 64, 66, the dummy nanostructures 68, and/or the semiconductor fins 62. Timed etch processes may be used to stop the etching of the source/drain recesses 94 after the source/drain recesses 94 reach a desired depth.

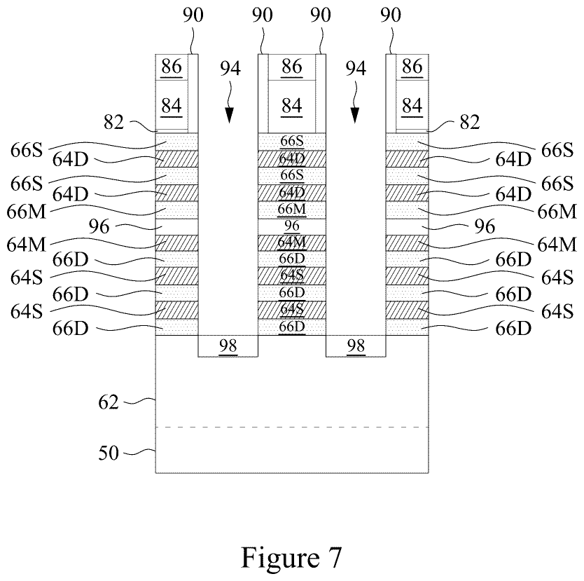

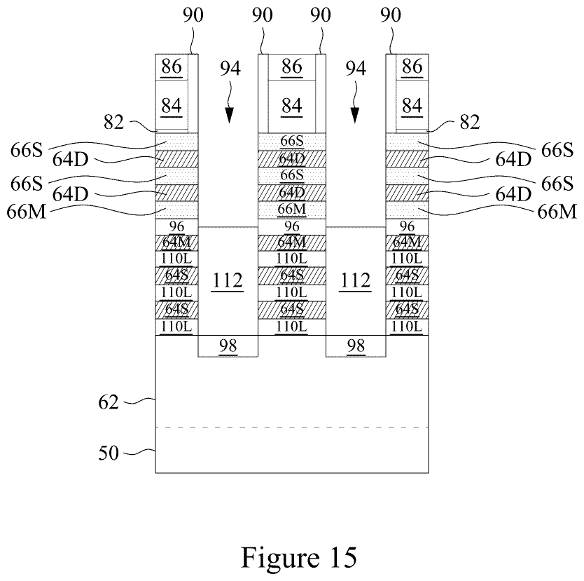

As subsequently described in greater detail, the lower dummy nanostructures 66D and the upper dummy nanostructures 64D will be replaced with dielectric structures, which are dummy structures. Specifically, and as subsequently described for FIGS. 7-14, the lower dummy nanostructures 66D will be replaced with lower dielectric structures. Additionally, and as subsequently described for FIGS. 15-18, the upper dummy nanostructures 64D will be replaced with upper dielectric structures. The dummy structures that replace the lower dummy nanostructures 66D and the upper dummy nanostructures 64D will be formed of a dielectric material. During a subsequent gate replacement process, dummy structures formed of dielectric material may be more easily removed than dummy structures formed of semiconductor material. For example, the etching of a dielectric material may be more easily controlled than the etching of a semiconductor material, particularly when the lower semiconductor nanostructures 64S and the upper semiconductor nanostructures 66S are formed of different semiconductor materials, which may increase the gate replacement processing window.

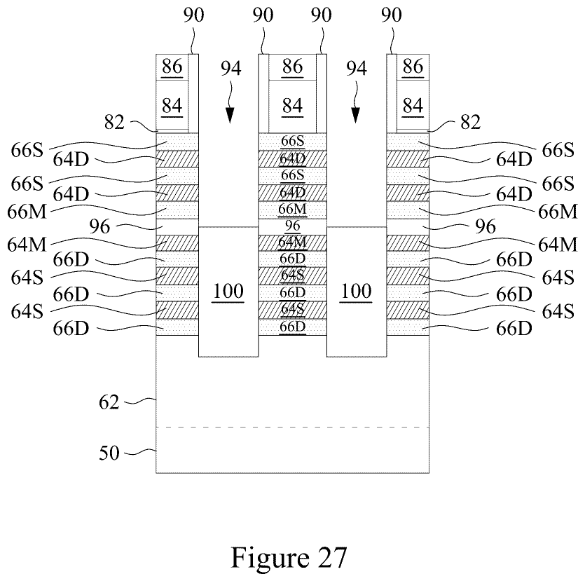

In this embodiment, the lower dummy nanostructures 66D are replaced with lower dielectric structures before the upper dummy nanostructures 64D are replaced with upper dielectric structures. Other processes may be utilized. In another embodiment (subsequently described for FIGS. 27-38), the lower dummy nanostructures 66D are replaced with lower dielectric structures after the upper dummy nanostructures 64D are replaced with upper dielectric structures.

In FIG. 7, the dummy nanostructures 68 are replaced with isolation structures 96. Specifically, the dummy nanostructures 68 are removed to form openings between the first middle nanostructures 64M and the second middle nanostructures 66M, and the isolation structures 96 are formed in the openings between the first middle nanostructures 64M and the second middle nanostructures 66M. The dummy nanostructures 68 may be removed with any acceptable etch process. The etching is selective to the material of the dummy nanostructures 68 (e.g., selectively etches the material of the dummy nanostructures 68 at a faster rate than the materials of the nanostructures 64, 66). The etching may be isotropic. In some embodiments, the etching process thins the first middle nanostructures 64M and the second middle nanostructures 66M. The dummy gates 84 may adhere to and support the nanostructures 64, 66 so that the nanostructures 64, 66 do not collapse after the removal of the dummy nanostructures 68. The isolation structures 96 may be formed by conformally forming an insulating material in the source/drain recesses 94 (including in the openings between the first middle nanostructures 64M and the second middle nanostructures 66M) and then subsequently etching the insulating material. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic. For example, the etch process may be a dry etch such as a RIE, a NBE, or the like. The insulating material, when etched, has portions remaining in the openings between the first middle nanostructures 64M and the second middle nanostructures 66M (thus forming the isolation structures 96). The insulating material, when etched, may also have residual portions left in the lower portions of the source/drain recesses 94 (thus forming a residual dielectric 98).

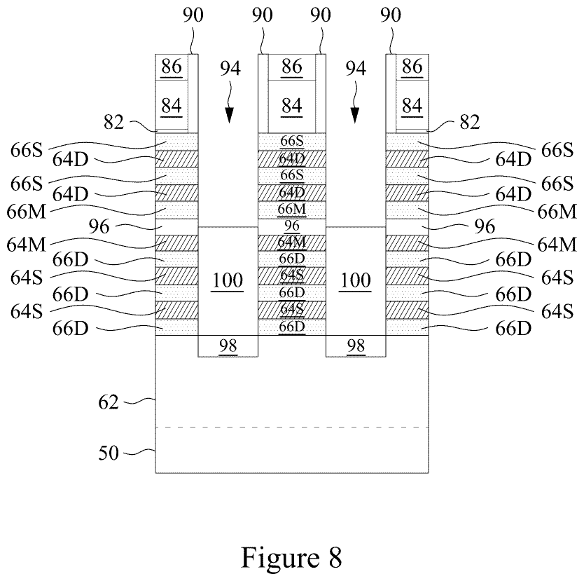

In FIG. 8, a sacrificial dielectric 100 is formed in the lower portions of the source/drain recesses 94 and on the residual dielectric 98 (if present). The sacrificial dielectric 100 is disposed on the sidewalls of the lower semiconductor nanostructures 64S, the first middle nanostructures 64M, and the lower dummy nanostructures 66D. The sacrificial dielectric 100 may be formed by conformally forming a dielectric material and subsequently recessing the dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. The dielectric material of the sacrificial dielectric 100 has a high etching selectivity to the dielectric material of the residual dielectric 98 (if present) and the isolation structures 96. Any acceptable etch process, such as a dry etch, a wet etch, the like, or a combination thereof, may be performed to recess the dielectric material. The etching may be isotropic, such as an etch-back process that removes the dielectric material from the upper portions of the source/drain recesses 94. In various embodiments, the dielectric material of the sacrificial dielectric 100 may be etched by a wet etch using dilute hydrofluoric acid, a dry etch using hydrofluoric acid and nitrogen trifluoride without plasma, a dry etch using hydrogen gas and nitrogen trifluoride with plasma, a dry etch using CHₓF_{y} with plasma, or the like. The dielectric material, when etched, has portions left in the lower portions of the source/drain recesses 94 (thus forming the sacrificial dielectric 100).

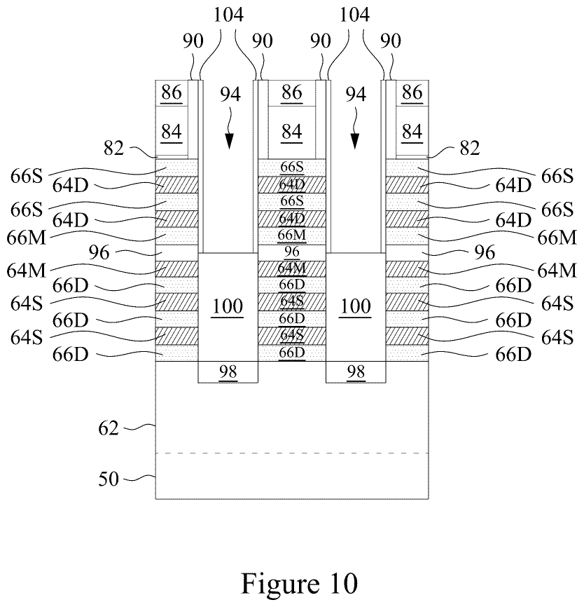

As subsequently described in greater detail, dummy spacers 104 (see FIG. 10) will be formed over the sacrificial dielectric 100 and in the upper portions of the source/drain recesses 94. The dummy spacers 104 are disposed on the sidewalls of the upper dummy nanostructures 64D, the upper semiconductor nanostructures 66S, the second middle nanostructures 66M, and the gate spacers 90. The dummy spacers 104 may be formed by conformally forming a dielectric material and subsequently etching the dielectric material.

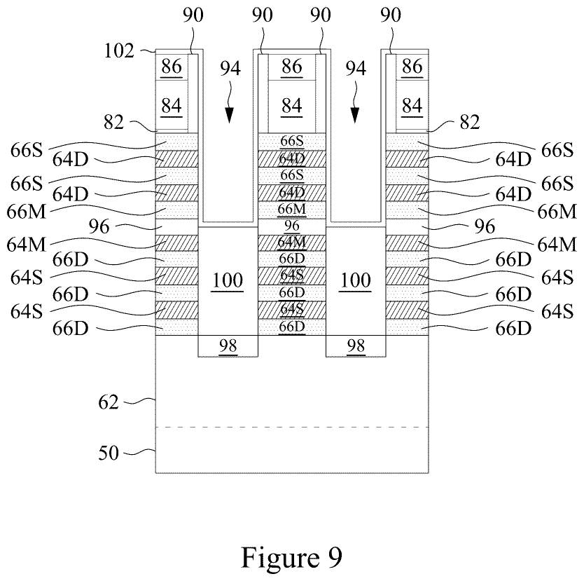

In FIG. 9, a dummy layer 102 is conformally formed over the sacrificial dielectric 100, the gate spacers 90, and the masks 86 (if present) or the dummy gates 84. The dummy layer 102 may be formed of a dielectric material. Acceptable dielectric materials may include silicon oxide, silicon nitride, silicon oxynitride, silicon oxycarbonitride, aluminum oxide, combinations thereof, or the like, which may be formed by a deposition process such as chemical vapor deposition (CVD), atomic layer deposition (ALD), or the like. Other dielectric materials formed by any acceptable process may be used. The dielectric material of the dummy layer 102 has a high etching selectivity to the dielectric material of the sacrificial dielectric 100 and the dielectric material of the isolation structures 96. In some embodiments, the dummy layer 102 and/or the sacrificial dielectric 100 each comprise silicon oxycarbonitride, and an amount of carbon in each of the dummy layer 102 and the sacrificial dielectric 100 may be selected to tune an etching selectivity of the subsequently formed dummy spacers and/or the sacrificial dielectric 100. Further, although the dummy layer 102 is illustrated as a single layer having a uniform material composition, the dummy layer 102 may have a multilayer structure including different layers of different dielectric materials.

In FIG. 10, the dummy layer 102 is patterned to form dummy spacers 104. Any acceptable etch process, such as a dry etch, may be performed to pattern the dummy layer 102. The etching may be anisotropic. The etching is selective to the dielectric material of the dummy layer 102 (e.g., selectively etches the material of the dummy layer 102 at a faster rate than the material of the sacrificial dielectric 100). The dummy layer 102, when etched, has portions left on the sidewalls of the upper dummy nanostructures 64D, the upper semiconductor nanostructures 66S, the second middle nanostructures 66M, and the gate spacers 90 (thus forming the dummy spacers 104).

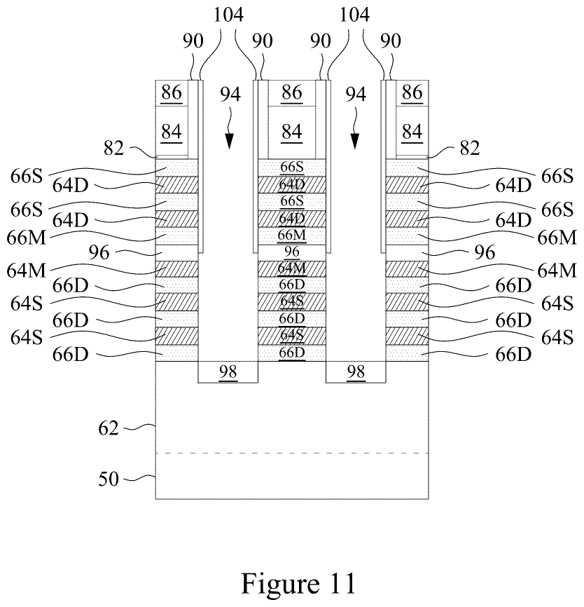

In FIG. 11, the sacrificial dielectric 100 is removed from the source/drain recesses 94. Any acceptable etch process, such as a dry etch, a wet etch, the like, or a combination thereof, may be performed to remove the sacrificial dielectric 100. The etching may be isotropic. The etching is selective to the material of the sacrificial dielectric 100 (e.g., selectively etches the material of the sacrificial dielectric 100 at a faster rate than the materials of the nanostructures 64, 66, the isolation structures 96, the residual dielectric 98, and the dummy spacers 104). In some embodiments, the etching process etches the material of the sacrificial dielectric 100 at least 50 times faster than the material of the first nanostructures 64, at least 50 times faster than the material of the second nanostructures 66, and at least 50 times faster than the material of the isolation structures 96. Removing the sacrificial dielectric 100 exposes the sidewalls of the lower semiconductor nanostructures 64S and the lower dummy nanostructures 66D, while the sidewalls of the upper dummy nanostructures 64D and the upper semiconductor nanostructures 66S remain covered by the dummy spacers 104.

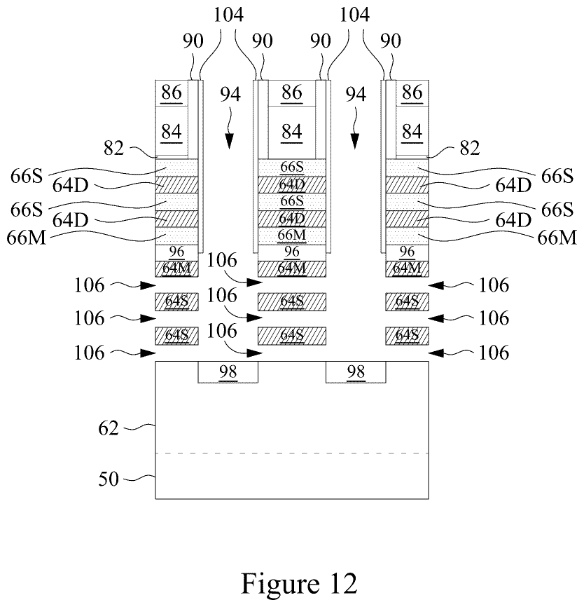

In FIG. 12, the lower dummy nanostructures 66D are removed to form openings 106 between the first nanostructures 64. The openings 106 will subsequently be filled with dummy structures. The openings 106 may be formed by removing the lower dummy nanostructures 66D with any acceptable etch process. The etching is selective to the material of the second nanostructures 66 (e.g., selectively etches the material of the second nanostructures 66 at a faster rate than the material of the first nanostructures 64). The etching may be isotropic. In various embodiments, the semiconductor material of the lower dummy nanostructures 66D may be etched by a dry etch using fluorine, chlorine trifluoride, and ammonia without plasma; a dry etch using hydrogen and nitrogen trifluoride with plasma; or the like. The dummy gates 84 may adhere to and support the nanostructures 64, 66 so that the nanostructures 64, 66 do not collapse after the formation of the openings 106.

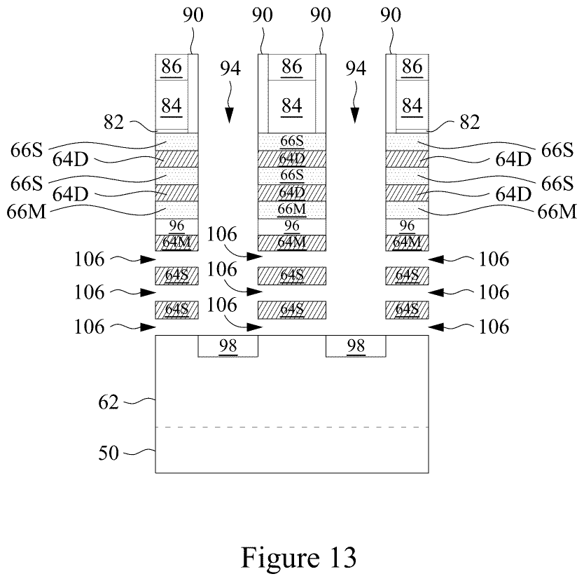

In FIG. 13, the dummy spacers 104 are removed from the source/drain recesses 94. Any acceptable etch process, such as a dry etch, a wet etch, the like, or a combination thereof, may be performed to remove the dummy spacers 104. The etching may be isotropic. The etching is selective to the material of the dummy spacers 104 (e.g., selectively etches the material of the dummy spacers 104 at a faster rate than the materials of the nanostructures 64, 66).

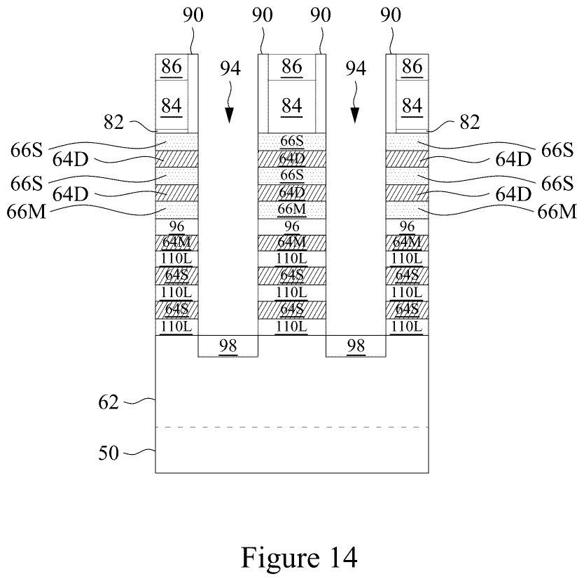

In FIG. 14, lower dielectric structures 110L are formed in the openings 106. The lower dielectric structures 110L may be formed by conformally forming an insulating material in the source/drain recesses 94 (including in the openings 106) and then subsequently etching the insulating material. The insulating material may be a carbon-free dielectric material, such as silicon nitride, silicon oxide, aluminum oxide, or the like. Other low-dielectric constant (low-k) materials having a k-value less than about 3.5 may be utilized. The insulating material of the lower dielectric structures 110L has a high etching selectivity to the materials of the isolation structures 96 and the nanostructures 64, 66. The insulating material may be formed by a deposition process, such as ALD, CVD, or the like. The etching of the insulating material may be anisotropic. For example, the etch process may be a dry etch such as a RIE, a NBE, or the like. In various embodiments, the dielectric material of the lower dielectric structures 110L may be etched by a wet etch using dilute hydrofluoric acid, a dry etch using hydrofluoric acid and nitrogen trifluoride without plasma, a dry etch using hydrogen gas and nitrogen trifluoride with plasma, a dry etch using CHₓF_{y} with plasma, or the like. The insulating material, when etched, has portions remaining in the openings 106 (thus forming the lower dielectric structures 110L). The etching process may (or may not) also recess the residual dielectric 98.

In FIG. 15, a sacrificial dielectric 112 is formed in the lower portions of the source/drain recesses 94 and on the residual dielectric 98 (if present). The sacrificial dielectric 112 is disposed on the sidewalls of the lower semiconductor nanostructures 64S, the first middle nanostructures 64M, and the lower dielectric structures 110L. The sacrificial dielectric 112 may be formed by conformally forming a dielectric material and subsequently recessing the dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. The dielectric material of the sacrificial dielectric 112 has a high etching selectivity to the dielectric materials of the lower dielectric structures 110L, the residual dielectric 98 (if present), and the isolation structures 96. Any acceptable etch process, such as a dry etch, a wet etch, the like, or a combination thereof, may be performed to recess the dielectric material. The etching may be isotropic, such as an etch-back process that removes the dielectric material from the upper portions of the source/drain recesses 94. The dielectric material, when etched, has portions left in the lower portions of the source/drain recesses 94 (thus forming the sacrificial dielectric 112).

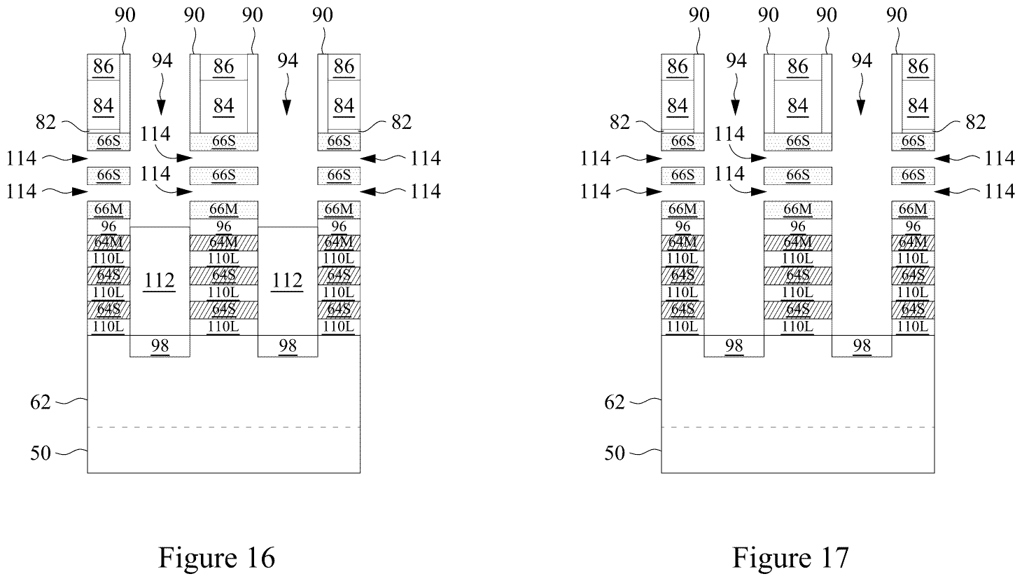

In FIG. 16, the upper dummy nanostructures 64D are removed to form openings 114 between the second nanostructures 66. The openings 114 will subsequently be filled with dummy structures. The openings 114 may be formed by removing the upper dummy nanostructures 64D with any acceptable etch process. The etching is selective to the material of the first nanostructures 64 (e.g., selectively etches the material of the first nanostructures 64 at a faster rate than the material of the second nanostructures 66). The etching may be isotropic. In various embodiments, the semiconductor material of the upper dummy nanostructures 64D may be etched by a dry etch using fluorine, chlorine trifluoride, and ammonia without plasma; a dry etch using hydrogen, nitrogen trifluoride, and CₓF_{y} with plasma; or the like. The dummy gates 84 may adhere to and support the nanostructures 64, 66 so that the nanostructures 64, 66 do not collapse after the formation of the openings 114.

In FIG. 17, the sacrificial dielectric 112 is removed from the source/drain recesses 94. Any acceptable etch process, such as a dry etch, a wet etch, the like, or a combination thereof, may be performed to remove the sacrificial dielectric 112. The etching may be isotropic. The etching is selective to the material of the sacrificial dielectric 112 (e.g., selectively etches the material of the sacrificial dielectric 112 at a faster rate than the materials of the lower dielectric structures 110L, the residual dielectric 98 (if present), and the isolation structures 96).

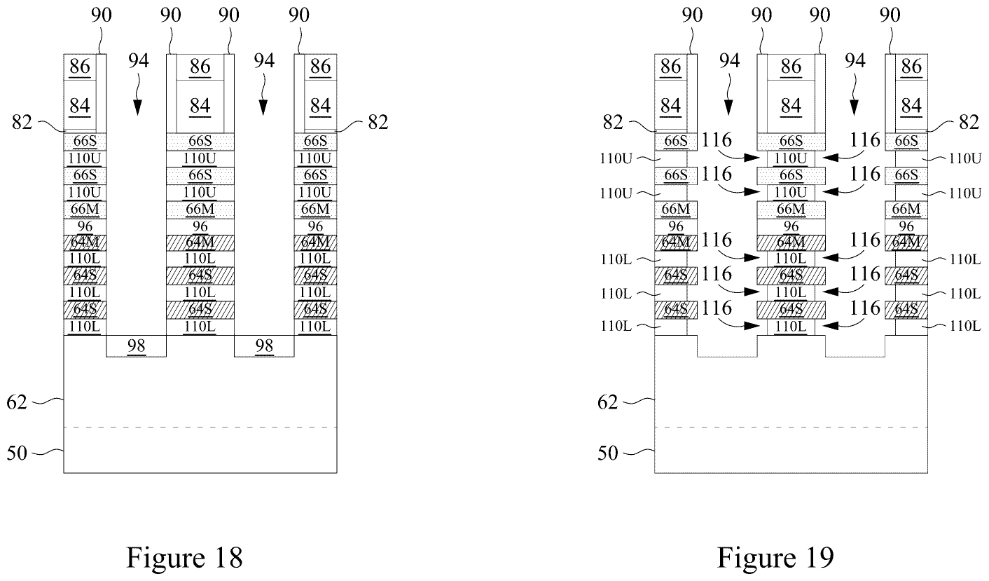

In FIG. 18, upper dielectric structures 110U are formed in the openings 114. The upper dielectric structures 110U may be formed in a similar manner as the lower dielectric structures 110L. The upper dielectric structures 110U and the lower dielectric structures 110L are each formed of the same insulating material. The upper dielectric structures 110U and the lower dielectric structures 110L may further be collectively referred to as the dielectric structures 110.

In FIG. 19, portions of the sidewalls of the dielectric structures 110 exposed by the source/drain recesses 94 are recessed to form sidewall recesses 116. The source/drain recesses 94 are thus laterally expanded. The sidewalls may be recessed by any acceptable etch process, such as one that is selective to the material of the dielectric structures 110 (e.g., selectively etches the material of the dielectric structures 110 at a faster rate than the materials of the nanostructures 64, 66 and the isolation structures 96). The etching may be isotropic. The etching process may (or may not) also remove the residual dielectric 98. Although sidewalls of the dielectric structures 110 are illustrated as being straight after the recessing, the sidewalls may be concave or convex.

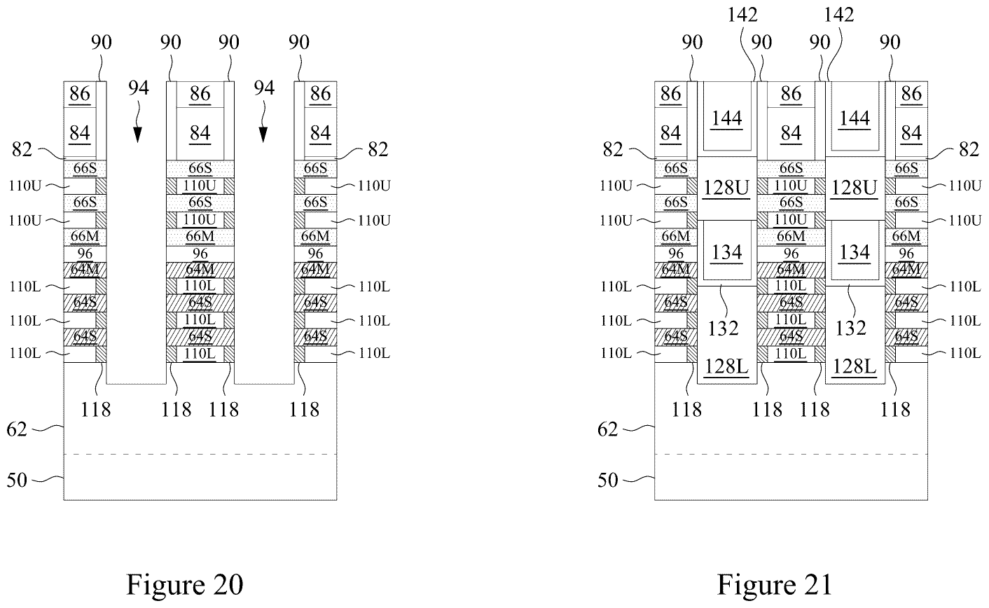

In FIG. 20, inner spacers 118 are formed in the sidewall recesses 116. The inner spacers 118 are disposed on the sidewalls of the dielectric structures 110, e.g., those sidewalls exposed by the sidewall recesses 116. As will be subsequently described in greater detail, source/drain regions will be subsequently formed in the source/drain recesses 94, and the dielectric structures 110 will be subsequently replaced with corresponding gate structures. The inner spacers 118 act as isolation features between the subsequently formed source/drain regions and the subsequently formed gate structures. Further, the inner spacers 118 may be used to prevent damage to the subsequently formed source/drain regions by subsequent etch processes, such as etch processes used to subsequently remove the dielectric structures 110.

As an example to form the inner spacers 118, an insulating material may be conformally formed in the sidewall recesses 116 and the source/drain recesses 94. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material of the inner spacers 118 has a high etching selectivity to the insulating material of the dielectric structures 110. The insulating material may be formed by a deposition process, such as ALD, CVD, or the like. The insulating material may then be etched. The etching of the insulating material may be anisotropic. For example, the etch process may be a dry etch such as a RIE, a NBE, or the like. The insulating material, when etched, has portions remaining in the sidewall recesses 116 (thus forming the inner spacers 118).

Although outer sidewalls of inner spacers 118 are illustrated as being flush with the sidewalls of the nanostructures 64, 66, the outer sidewalls of the inner spacers 118 may extend beyond or be recessed from the sidewalls of the nanostructures 64, 66. Thus, the inner spacers 118 may partially fill, completely fill, or overfill the sidewall recesses. Moreover, although the sidewalls of the inner spacers 118 are illustrated as being straight, those sidewalls may be concave or convex.

In FIG. 21, lower epitaxial source/drain regions 128L and upper epitaxial source/drain regions 128U are formed in the source/drain recesses 94. A first contact etch stop layer (CESL) 132 and/or a first inter-layer dielectric (ILD) 134 may also be formed in the source/drain recesses 94. The first ILD 134 is between the upper epitaxial source/drain regions 128U and the lower epitaxial source/drain regions 128L. The lower epitaxial source/drain regions 128L are for lower nanostructure-FETs of the CFETs, and the upper epitaxial source/drain regions 128U are for upper nanostructure-FETs of the CFETs. The first ILD 134 thus acts as isolation regions to prevent shorting of the lower and upper nanostructure-FETs. Additionally, a second CESL 142 and/or a second ILD 144 may also be formed on the upper epitaxial source/drain regions 128U.

The lower epitaxial source/drain regions 128L are in contact with the lower semiconductor nanostructures 64S and are not in contact with the upper semiconductor nanostructures 66S. In some embodiments, the lower epitaxial source/drain regions 128L exert stress in the respective channel regions of the lower semiconductor nanostructures 64S, thereby improving performance. The lower epitaxial source/drain regions 128L are formed in the source/drain recesses 94 such that each stack of the lower semiconductor nanostructures 64S is disposed between respective neighboring pairs of the lower epitaxial source/drain regions 128L. In some embodiments, the inner spacers 118 are used to separate the lower epitaxial source/drain regions 128L from the lower dielectric structures 110L, which will be replaced with gate structures in subsequent processes.

The lower epitaxial source/drain regions 128L are epitaxially grown in the lower portions of the source/drain recesses 94. For example, the lower epitaxial source/drain regions 128L may be grown laterally from exposed sidewalls of the lower semiconductor nanostructures 64S. During the epitaxy of the lower epitaxial source/drain regions 128L, the upper semiconductor nanostructures 66S may be masked to prevent undesired epitaxial growth on the upper semiconductor nanostructures 66S. After the lower epitaxial source/drain regions 128L are grown, the masks on the upper semiconductor nanostructures 66S may then be removed. The lower epitaxial source/drain regions 128L have a conductivity type that is suitable for the device type of the lower nanostructure-FETs. In some embodiments, the lower epitaxial source/drain regions 128L are n-type source/drain regions. For example, if the lower semiconductor nanostructures 64S are silicon, the lower epitaxial source/drain regions 128L may include materials exerting a tensile strain on the lower semiconductor nanostructures 64S, such as silicon, silicon carbide, phosphorous-doped silicon carbide, silicon phosphide, silicon arsenide, or the like. Other acceptable material for n-type source/drain regions may be utilized, such as a Group-IV semiconductor doped with a Group-III element. In some embodiments, the lower epitaxial source/drain regions 128L are p-type source/drain regions. For example, if the lower semiconductor nanostructures 64S are silicon-germanium, the lower epitaxial source/drain regions 128L may include materials exerting a compressive strain on the lower semiconductor nanostructures 64S, such as silicon-germanium, boron-doped silicon-germanium, boron-doped silicon, germanium, germanium tin, or the like. Other acceptable material for p-type source/drain regions may be utilized, such as a Group-IV semiconductor doped with a Group-V element. The lower epitaxial source/drain regions 128L may have surfaces raised from respective upper surfaces of the lower semiconductor nanostructures 64S and may have facets.

The lower epitaxial source/drain regions 128L may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the lower epitaxial source/drain regions 128L are in situ doped during growth.

As a result of the epitaxy processes used to form the lower epitaxial source/drain regions 128L, upper surfaces of the lower epitaxial source/drain regions 128L have facets which expand laterally outward beyond sidewalls of the nanostructures 64, 66. In some embodiments, adjacent lower epitaxial source/drain regions 128L remain separated after the epitaxy process is completed. In other embodiments, these facets cause adjacent lower epitaxial source/drain regions 128L of a same nanostructure-FET to merge.

The first ILD 134 is formed over the lower epitaxial source/drain regions 128L. The first ILD 134 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The first CESL 132 may be formed between the first ILD 134 and the lower epitaxial source/drain regions 128L. The first CESL 132 may be formed of a dielectric material having a high etching selectivity to the dielectric material of the first ILD 134, such as silicon nitride, silicon oxide, silicon oxynitride, or the like, which may be formed by any suitable deposition process, such as CVD, ALD, or the like.

The first CESL 132 and/or the first ILD 134 may be formed by depositing a material for the first CESL 132 and depositing a material for the first ILD 134, followed by a planarization process and then an etch-back process. In some embodiments, the first ILD 134 is initially etched, leaving the first CESL 132 unetched. An anisotropic etching process is then performed to remove the portions of the first CESL 132 that are higher than the first ILD 134. After the recessing, the sidewalls of the upper semiconductor nanostructures 66S are exposed.

The upper epitaxial source/drain regions 128U are in contact with the upper semiconductor nanostructures 66S and are not in contact with the lower semiconductor nanostructures 64S. In some embodiments, the upper epitaxial source/drain regions 128U exert stress in the respective channel regions of the upper semiconductor nanostructures 66S, thereby improving performance. The upper epitaxial source/drain regions 128U are formed in the source/drain recesses 94 such that each stack of the upper semiconductor nanostructures 66S is disposed between respective neighboring pairs of the upper epitaxial source/drain regions 128U. In some embodiments, the inner spacers 118 are used to separate the upper epitaxial source/drain regions 128U from the upper dielectric structures 110U, which will be replaced with gate structures in subsequent processes.

The upper epitaxial source/drain regions 128U are epitaxially grown in the upper portions of the source/drain recesses 94. For example, the upper epitaxial source/drain regions 128U may be grown laterally from exposed sidewalls of the upper semiconductor nanostructures 66S. The upper epitaxial source/drain regions 128U have a conductivity type that is suitable for the device type of the upper nanostructure-FETs. The conductivity type of the upper epitaxial source/drain regions 128U may be opposite the conductivity type of the lower epitaxial source/drain regions 128L. Put another way, the upper epitaxial source/drain regions 128U may be oppositely doped from the lower epitaxial source/drain regions 128L. In some embodiments, the upper epitaxial source/drain regions 128U are n-type source/drain regions. For example, if the upper semiconductor nanostructures 66S are silicon, the upper epitaxial source/drain regions 128U may include materials exerting a tensile strain on the upper semiconductor nanostructures 66S, such as silicon, silicon carbide, phosphorous-doped silicon carbide, silicon phosphide, silicon arsenide, or the like. In some embodiments, the upper epitaxial source/drain regions 128U are p-type source/drain regions. For example, if the upper semiconductor nanostructures 66S are silicon-germanium, the upper epitaxial source/drain regions 128U may include materials exerting a compressive strain on the upper semiconductor nanostructures 66S, such as silicon-germanium, boron-doped silicon-germanium, boron-doped silicon, germanium, germanium tin, or the like. The upper epitaxial source/drain regions 128U may have surfaces raised from respective upper surfaces of the upper semiconductor nanostructures 66S and may have facets.

The upper epitaxial source/drain regions 128U may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the upper epitaxial source/drain regions 128U are in situ doped during growth.

As a result of the epitaxy processes used to form the upper epitaxial source/drain regions 128U, upper surfaces of the upper epitaxial source/drain regions 128U have facets which expand laterally outward beyond sidewalls of the nanostructures 64, 66. In some embodiments, adjacent upper epitaxial source/drain regions 128U remain separated after the epitaxy process is completed. In other embodiments, these facets cause adjacent upper epitaxial source/drain regions 128U of a same nanostructure-FET to merge.

In this embodiment, the inner spacers 118 adjacent the upper epitaxial source/drain regions 128U are formed of the same dielectric material as the inner spacers 118 adjacent the lower epitaxial source/drain regions 128L. Other acceptable spacers may be utilized. In another embodiment (subsequently described for FIGS. 27-38), the inner spacers 118 adjacent the upper epitaxial source/drain regions 128U are formed of a different dielectric material than the inner spacers 118 adjacent the lower epitaxial source/drain regions 128L.

The second ILD 144 is deposited over the upper epitaxial source/drain regions 128U. The second ILD 144 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The second CESL 142 may be formed between the second ILD 144 and the upper epitaxial source/drain regions 128U. The second CESL 142 may be formed of a dielectric material having a high etching selectivity to the dielectric material of the second ILD 144, such as, silicon nitride, silicon oxide, silicon oxynitride, or the like, which may be formed by any suitable deposition process, such as CVD, ALD, or the like.

The second CESL 142 and/or the second ILD 144 may be formed by depositing a material for the second CESL 142 and depositing a material for the second ILD 144, followed by a planarization process. A removal process is then performed to level the top surfaces of the second ILD 144 with the top surfaces of the gate spacers 90 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, top surfaces of the second ILD 144, the gate spacers 90, and the masks 86 (if present) or the dummy gates 84 are substantially coplanar (within process variations). Accordingly, the top surfaces of the masks 86 (if present) or the dummy gates 84 are exposed through the second ILD 144. In the illustrated embodiment, the masks 86 remain after the removal process. In other embodiments, the masks 86 are removed such that the top surfaces of the dummy gates 84 are exposed through the second ILD 144.

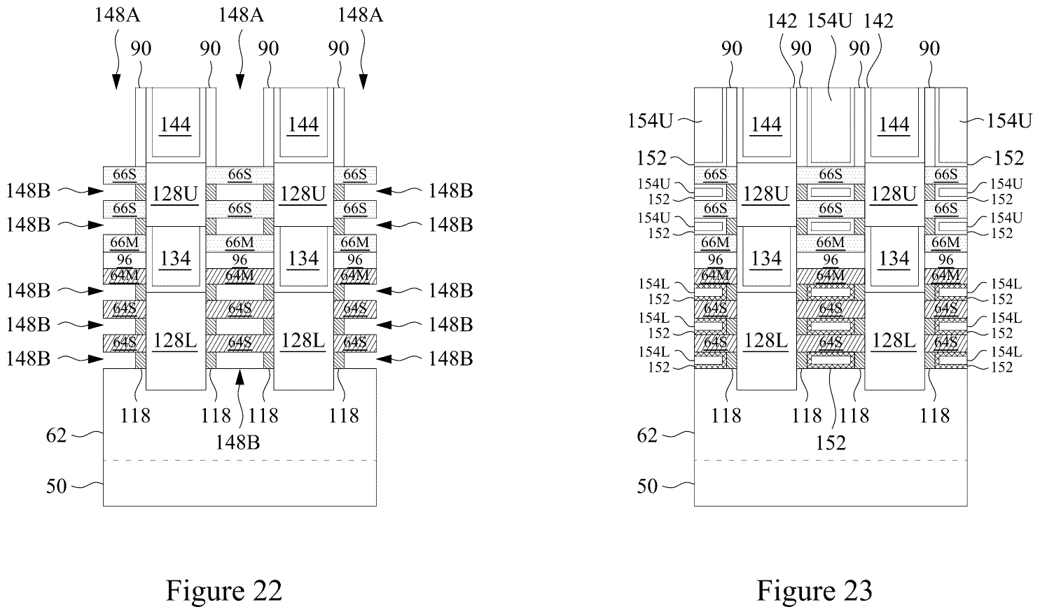

In FIG. 22, the dummy gates 84 are removed in one or more etching steps, so that recesses 148A are formed between the gate spacers 90. Portions of the dummy dielectrics 82 in the recesses 148A are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the second ILD 144, the inner spacers 118, the isolation structures 96, and the gate spacers 90. In various embodiments, the material of the dummy gates 84 may be etched by a dry etch using fluorine, chlorine trifluoride, and ammonia without plasma; a dry etch using hydrogen and nitrogen trifluoride with plasma; or the like. Each recess 148A between the gate spacers 90 exposes and/or overlies portions of nanostructures 64, 66 which act as the channel regions in the resulting devices. The portions of the nanostructures 64, 66 which act as the channel regions are disposed between neighboring pairs of the lower epitaxial source/drain regions 128L or between neighboring pairs of the upper epitaxial source/drain regions 128U. During the removal, the dummy dielectrics 82 may be used as etch stop layers when the dummy gates 84 are etched. The dummy dielectrics 82 may then be removed after the removal of the dummy gates 84.

The remaining portions of the dielectric structures 110 are then removed to form openings 148B in regions between the first nanostructures 64 and the second nanostructures 66. The remaining portions of the dielectric structures 110 can be removed by any acceptable etch process that selectively etches the material of the dielectric structures 110 at a faster rate than the materials of the nanostructures 64, 66, the isolation structures 96, and the inner spacers 118. The etching may be isotropic. In some embodiments, the etching process etches the material of the dielectric structures 110 at least 50 times faster than the material of the first nanostructures 64, at least 50 times faster than the material of the second nanostructures 66, at least 50 times faster than the material of the isolation structures 96, and at least 10 times faster than the material of the inner spacers 118. In some embodiments, a trim process (not separately illustrated) is performed to decrease the thicknesses of the exposed portions of the first nanostructures 64 and the second nanostructures 66, thereby expanding the openings 148B between the first nanostructures 64 and the second nanostructures 66.

As previously noted, the dielectric structures 110 are dummy structures formed of a dielectric material that may be more easily removed than dummy structures formed of semiconductor material. The dielectric material of the dielectric structures 110 has a high etching selectivity to the semiconductor materials of the first nanostructures 64 and the second nanostructures 66. Accordingly, the dielectric structures 110 may be removed without significantly removing the first nanostructures 64 and the second nanostructures 66, even when the first nanostructures 64 and the second nanostructures 66 are formed of different semiconductor materials.

The dielectric structures 110 are formed of a dielectric material that has a high etching selectivity to other dielectric materials, such as the dielectric material(s) of the isolation structures 96, and the inner spacers 118. In some embodiments, the dielectric structures 110 are removed by an etching process, and the dielectric material(s) of the isolation structures 96 and the inner spacers 118 contain an element that causes those dielectric material(s) to be resistant to the etching process. The isolation structures 96 and the inner spacers 118 may be formed of the same dielectric material containing the same element, and the dielectric material of the dielectric structures 110 may be free of that element. For example, as noted above, the isolation structures 96 and the inner spacers 118 may each be formed of a carbon-containing dielectric material, and the dielectric structures 110 may be formed of a carbon-free dielectric material. The etching process may include a wet etch that selectively etches the carbon-free dielectric material at a faster rate than the carbon-containing dielectric material. In some embodiments, the isolation structures 96 and the inner spacers 118 are each formed of silicon oxycarbonitride; the dielectric structures 110 are formed of silicon nitride; and the dielectric structures 110 are removed to form the openings 148B between the first nanostructures 64 and the second nanostructures 66 by a wet etch with phosphoric acid (H₃PO₄). In some embodiments, the isolation structures 96 and the inner spacers 118 are each formed of silicon oxycarbonitride; the dielectric structures 110 are formed of silicon oxide; and the dielectric structures 110 are removed to form the openings 148B between the first nanostructures 64 and the second nanostructures 66 by a wet etch with dilute hydrofluoric acid. In some embodiments, the isolation structures 96 and the inner spacers 118 are each formed of silicon oxycarbonitride; the dielectric structures 110 are formed of aluminum oxide; and the dielectric structures 110 are removed to form the openings 148B between the first nanostructures 64 and the second nanostructures 66 by a wet etch with phosphoric acid (H₃PO₄) and a low-temperature sulfuric peroxide mixture (e.g., a mixture of sulfuric acid and hydrogen peroxide) at a temperature in the range of 70° C. to 100° C. Other acceptable etching processes may be utilized to remove the dielectric structures 110. In various embodiments, the material of the dielectric structures 110 may be etched by a wet etch using dilute hydrofluoric acid, a dry etch using hydrofluoric acid and nitrogen trifluoride without plasma, or the like.

In some embodiments, the dielectric structures 110, the isolation structures 96, and the inner spacers 118 each contain a same element that causes them to be resistant to the etching process. The dielectric material of the dielectric structures 110 have a lower concentration of that element than the dielectric material(s) of the isolation structures 96 and the inner spacers 118. For example, the dielectric structures 110 may have a low carbon concentration, such as a carbon concentration of less than about 6%. Similarly, the isolation structures 96 and the inner spacers 118 may have a high carbon concentration, such as a carbon concentration of greater than about 6%.

In FIG. 23, gate dielectrics 152 and gate electrodes 154 (including lower gate electrodes 154L and upper gate electrodes 154U) are formed for replacement gates. Each respective pair of a gate dielectric 152 and a gate electrode 154 (including an upper gate electrode 154U and/or a lower gate electrode 154L) may be collectively referred to as a “gate structure.” Each gate structure extends along at least three sides (e.g., a top surface, a sidewall, and a bottom surface) of a channel region of a lower semiconductor nanostructure 64S and/or an upper semiconductor nanostructures 66S. The gate structures may also extend along sidewalls and/or a top surface of a semiconductor fin 62.

The gate dielectrics 152 include one or more gate dielectric layer(s) disposed around the lower semiconductor nanostructures 64S, the upper semiconductor nanostructures 66S, and the isolation structures 96. Specifically, the gate dielectrics 152 are disposed on the top surfaces of the semiconductor fins 62; on the top surfaces, the sidewalls, and the bottom surfaces of the lower semiconductor nanostructures 64S and the upper semiconductor nanostructures 66S; on the sidewalls of the gate spacers 90; on the sidewalls of the isolation structures 96; and on the sidewalls of the inner spacers 118. The gate dielectrics 152 wrap around all (e.g., four) sides of the lower semiconductor nanostructures 64S and the upper semiconductor nanostructures 66S. The gate dielectrics 152 may be formed of an oxide such as silicon oxide or a metal oxide, a silicate such as a metal silicate, combinations thereof, multi-layers thereof, or the like. Additionally or alternatively, the gate dielectrics 152 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 152 may be formed by molecular-beam deposition (MBD), ALD, PECVD, or the like. Although single-layered gate dielectrics 152 are illustrated, the gate dielectrics 152 may include any number of interfacial layers and any number of main layers. For example, the gate dielectrics 152 may include an interfacial layer and an overlying high-k dielectric layer.

The lower gate electrodes 154L include one or more gate electrode layer(s) disposed over the gate dielectrics 152 and around the lower semiconductor nanostructures 64S. The lower gate electrodes 154L are disposed in the lower portions of the recesses 148A between the gate spacers 90 and in the openings 148B between the first nanostructures 64. The lower gate electrodes 154L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 154L may include any number of work function tuning layers, any number of barrier layers, any number of glue layers, and a fill material.

The lower gate electrodes 154L are formed of material(s) that are suitable for the device type of the lower nanostructure-FETs. For example, the lower gate electrodes 154L may include one or more work function tuning layer(s) formed of work function tuning metal(s) that are suitable for the device type of the lower nanostructure-FETs. In some embodiments, the lower gate electrodes 154L include an n-type work function tuning layer, which may be formed of an n-type work function tuning metal such as titanium aluminum, titanium aluminum carbide, tantalum aluminum, tantalum carbide, combinations thereof, or the like. In some embodiments, the lower gate electrodes 154L include a p-type work function tuning layer, which may be formed of a p-type work function tuning metal such as titanium nitride, tantalum nitride, combinations thereof, or the like. Additionally or alternatively, the lower gate electrodes 154L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The upper gate electrodes 154U include one or more gate electrode layer(s) disposed over the gate dielectrics 152 and around the upper semiconductor nanostructures 66S. The upper gate electrodes 154U are disposed in the upper portions of the recesses 148A between the gate spacers 90 and in the openings 148B between the upper semiconductor nanostructures 66S. The upper gate electrodes 154U may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the upper gate electrodes 154U may include any number of work function tuning layers, any number of barrier layers, any number of glue layers, and a fill material.

The upper gate electrodes 154U are formed of material(s) that are suitable for the device type of the upper nanostructure-FETs. For example, the upper gate electrodes 154U may include one or more work function tuning layer(s) formed of work function tuning metal(s) that are suitable for the device type of the upper nanostructure-FETs. In some embodiments, the upper gate electrodes 154U include an n-type work function tuning layer, which may be formed of an n-type work function tuning metal such as titanium aluminum, titanium aluminum carbide, tantalum aluminum, tantalum carbide, combinations thereof, or the like. In some embodiments, the upper gate electrodes 154U include a p-type work function tuning layer, which may be formed of a p-type work function tuning metal such as titanium nitride, tantalum nitride, combinations thereof, or the like. The work function tuning metal(s) of the upper gate electrodes 154U may be different than the work function tuning metal(s) of the lower gate electrodes 154L. Additionally or alternatively, the upper gate electrodes 154U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements the upper gate electrodes 154U may be different than the dipole-inducing elements of the lower gate electrodes 154L.

In some embodiments, isolation layers (not separately illustrated) are formed between the lower gate electrodes 154L and the upper gate electrodes 154U. The isolation layers act as isolation features between the lower gate electrodes 154L and the upper gate electrodes 154U. The isolation layers may be formed of a dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. In embodiments where the isolation layers are formed, the isolation layers and the isolation structures 96 together isolate the upper gate electrodes 154U from the lower gate electrodes 154L. Accordingly, an upper nanostructure-FET may be isolated from a lower nanostructure-FET by a combination of an isolation structure 96 and an isolation layer. In some embodiments where the isolation layers are omitted, an upper nanostructure-FET may be coupled to a lower nanostructure-FET. When the isolation layers are omitted, the lower gate electrodes 154L may be physically and electrically coupled to the upper gate electrodes 154U.

As an example to form the gate structures, one or more gate dielectric layer(s) may be deposited in the recesses 148A between the gate spacers 90 and the openings 148B between the first nanostructures 64 and the second nanostructures 66. The gate dielectric layer(s) may also be deposited on the top surfaces of the second ILD 144 and the gate spacers 90. Subsequently, one or more lower gate electrode layer(s) may be deposited on the gate dielectric layer(s), and in the remaining portions of the recesses 148A between the gate spacers 90 and the openings 148B between the first nanostructures 64 and the second nanostructures 66. The lower gate electrode layer(s) may then be recessed. Any acceptable etch process, such as a dry etch, a wet etch, the like, or a combination thereof, may be performed to recess the lower gate electrode layer(s). The etching may be isotropic, such as an etch-back process that removes the lower gate electrode layer(s) from the upper portions of the recesses 148A between the gate spacers 90, such that the lower gate electrode layer(s) remain in the openings 148B between the first nanostructures 64. In embodiments where the isolation layers are formed, an isolation material is conformally formed on the lower gate electrode layer(s) and then recessed. Any acceptable etch process, such as a dry etch, a wet etch, the like, or a combination thereof, may be performed to recess the isolation material. Subsequently, one or more upper gate electrode layer(s) may be deposited on the isolation material (if present) or the lower gate electrode layer(s), and in the remaining portions of the recesses 148A between the gate spacers 90 and the openings 148B between the first nanostructures 64 and the second nanostructures 66. A removal process is performed to remove the excess portions of the upper gate electrode layer(s), which excess portions are over the top surfaces of the gate spacers 90 and the second ILD 144, such that the upper gate electrode layer(s) remain in the openings 148B between the second nanostructures 66. In some embodiments, a planarization process such as a chemical mechanical polish (CMP), an etch-back process, combinations thereof, or the like may be utilized. The gate dielectric layer(s), after the removal process, have portions remaining in the recesses 148A between the gate spacers 90 and the openings 148B between the first nanostructures 64 and the second nanostructures 66 (thus forming the gate dielectrics 152). The lower gate electrode layer(s), after the removal process, have portions left in the lower portions of the recesses 148A between the gate spacers 90 and in the openings 148B between the first nanostructures 64 (thus forming the lower gate electrodes 154L). The upper gate electrode layer(s), after the removal process, have portions left in the upper portions of the recesses 148A between the gate spacers 90 and in the openings 148B between the second nanostructures 66 (thus forming the upper gate electrodes 154U). When a planarization process is utilized, the top surfaces of the gate spacers 90, the second ILD 144, the gate dielectrics 152, and the upper gate electrodes 154U are coplanar (within process variations).

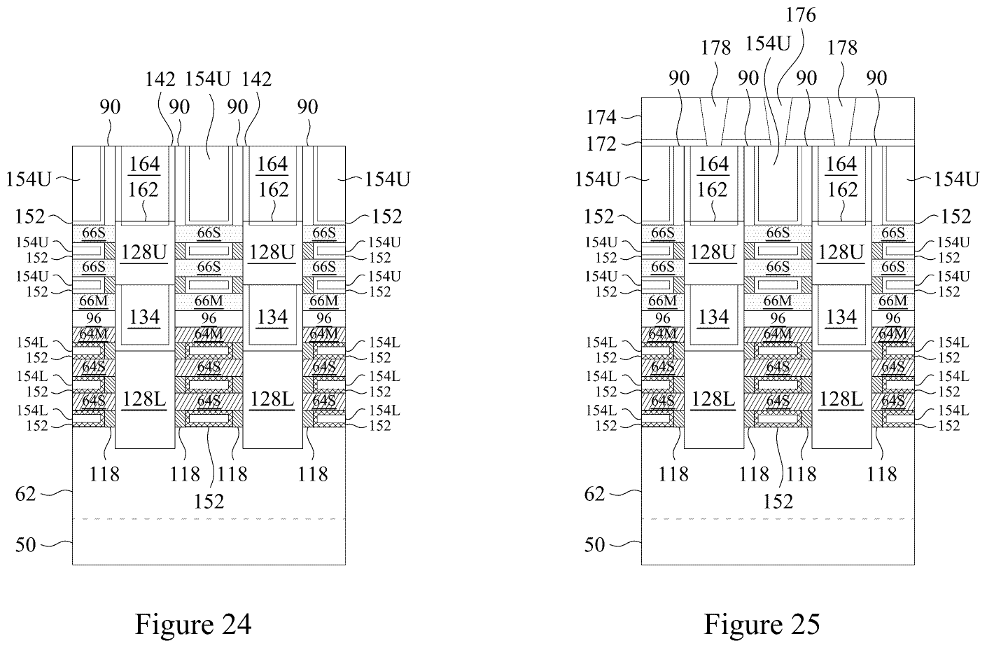

In FIG. 24, source/drain contacts 164 are formed through the second ILD 144 to electrically couple to the upper epitaxial source/drain regions 128U and/or the lower epitaxial source/drain regions 128L. As an example to form the source/drain contacts 164, openings for the source/drain contacts 164 are formed through the second ILD 144 and the second CESL 142. The openings may be formed using acceptable photolithography and etching techniques. In the illustrated embodiment, the openings are formed by a self-aligned contact (SAC) process. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 90, the second ILD 144 (see FIG. 22), and the upper gate electrodes 154U. The remaining liner and conductive material form the source/drain contacts 164 in the openings. In some embodiments, a planarization process such as a chemical mechanical polish (CMP), an etch-back process, combinations thereof, or the like is utilized. After the planarization process, the top surfaces of the gate spacers 90, the second ILD 144 (see FIG. 22), the upper gate electrodes 154U, and the source/drain contacts 164 are substantially coplanar (within process variations).

Optionally, metal-semiconductor alloy regions 162 are formed at the interfaces between the source/drain regions 128 and the source/drain contacts 164. The metal-semiconductor alloy regions 162 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 162 can be formed before the material(s) of the source/drain contacts 164 by depositing a metal in the openings for the source/drain contacts 164 and then performing a thermal anneal process. The metal can be any metal capable of reacting with the semiconductor materials (e.g., silicon, silicon-germanium, germanium, etc.) of the source/drain regions 128 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 164, such as from surfaces of the metal-semiconductor alloy regions 162. The material(s) of the source/drain contacts 164 can then be formed on the metal-semiconductor alloy regions 162.

In FIG. 25, a third ILD 174 is deposited over the gate spacers 90, the second ILD 144, the upper gate electrodes 154U, and the source/drain contacts 164. In some embodiments, the third ILD 174 is a flowable film formed by a flowable CVD method, which is subsequently cured. In some embodiments, the third ILD 174 is formed of a dielectric material such as PSG, BSG, BPSG, USG, or the like, which may be deposited by any suitable method, such as CVD, PECVD, or the like.

In some embodiments, an etch stop layer (ESL) 172 is formed between the third ILD 174 and the gate spacers 90, the second ILD 144, the upper gate electrodes 154U, and the source/drain contacts 164. The ESL 172 may include a dielectric material having a high etching selectivity to the dielectric material of the third ILD 174, such as, silicon nitride, silicon oxide, silicon oxynitride, or the like.

Gate contacts 176 and source/drain vias 178 are formed through the third ILD 174 to electrically couple to, respectively, the upper gate electrodes 154U and the source/drain contacts 164. As an example to form the gate contacts 176 and the source/drain vias 178, openings for the gate contacts 176 and the source/drain vias 178 are formed through the third ILD 174 and the ESL 172. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 174. The remaining liner and conductive material form the gate contacts 176 and the source/drain vias 178 in the openings. The gate contacts 176 and the source/drain vias 178 may be formed in distinct processes, or may be formed in the same process. Although shown as being formed in the same cross-section, it should be appreciated that each of the gate contacts 176 and the source/drain vias 178 may be formed in different cross-sections, which may avoid shorting of the contacts.

The active devices as illustrated are collectively referred to as a device layer. In some embodiments, contacts to the lower gate electrodes 154L and the lower source/drain regions 128L may be made through a backside of the device layer (e.g., a side opposite to the source/drain contacts 164).

FIG. 26 is a view of CFETs, in accordance with some embodiments. FIG. 26 illustrates a cross-sectional view along a similar cross-section as reference cross-section A-A′ in FIG. 1. This embodiment is similar to the embodiment of FIG. 25, except the first semiconductor material of the first nanostructures 64 is a semiconductor material for n-type devices, and the second semiconductor material of the second nanostructures 66 is a semiconductor material for p-type devices.

Embodiments may achieve advantages. Forming the dielectric structures 110 between the first nanostructures 64 and the second nanostructures 66 increases a processing window for a gate replacement process. Specifically, the dielectric material of the dielectric structures 110 has a high etching selectivity to the semiconductor materials of the first nanostructures 64 and the second nanostructures 66. Accordingly, during the gate replacement process, the dielectric structures 110 may be removed without significantly removing the first nanostructures 64 and the second nanostructures 66. The lower semiconductor nanostructures 64S and the upper semiconductor nanostructures 66S may thus be formed of different semiconductor materials, which may be particularly advantageous when the lower semiconductor nanostructures 64S and the upper semiconductor nanostructures 66S are for different types of devices. For example, the lower nanostructure-FETs may have a different threshold voltage than the upper nanostructure-FETs. Additionally, forming the dielectric structures 110 of the dielectric material may improve the line width ratio of the inner spacers 118 and the gate electrodes 154.

In the previously described embodiments, the lower dielectric structures 110L are formed before the upper dielectric structures 110U. Other processes may be utilized. In subsequently described embodiments, the lower dielectric structures 110L are formed after the upper dielectric structures 110U.

FIGS. 27-38 are views of intermediate stages in the manufacturing of CFETs, in accordance with some other embodiments. FIGS. 27, 28, 29, 30, 31, 32, 33, 34, 35, 36, 37, and 38 illustrate cross-sectional views along a similar cross-section as reference cross-section A-A′ in FIG. 1.

In FIG. 27, the structure of FIG. 7 is obtained. In this embodiment, no residual dielectric from the isolation structures 96 remains in the lower portions of the source/drain recesses 94. A sacrificial dielectric 100 is formed in the lower portions of the source/drain recesses 94. The sacrificial dielectric 100 is disposed on the sidewalls of the lower semiconductor nanostructures 64S, the first middle nanostructures 64M, and the lower dummy nanostructures 66D. The sacrificial dielectric 100 may be formed in a similar manner as that previously described for FIG. 8.

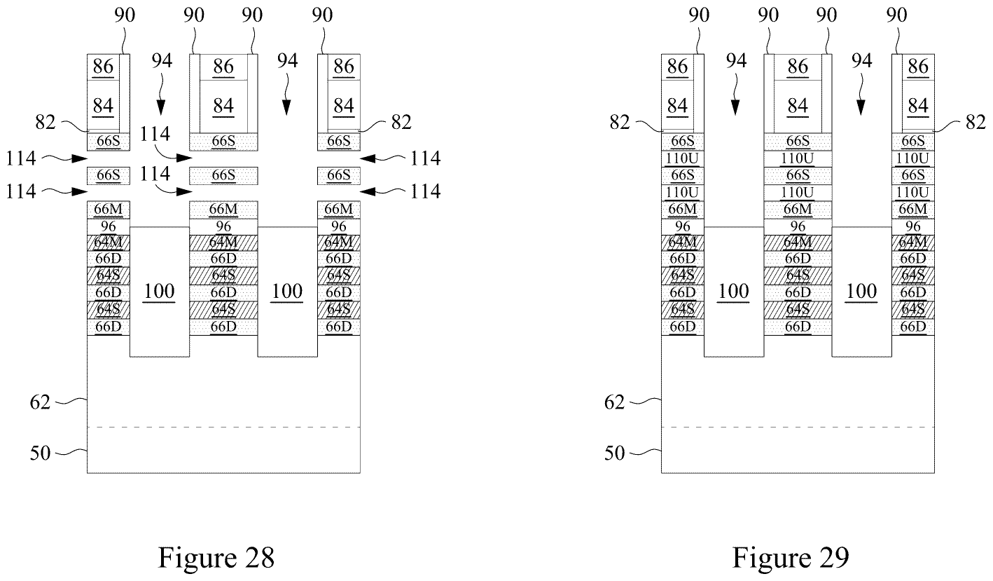

In FIG. 28, the upper dummy nanostructures 64D are removed to form openings 114 between the second nanostructures 66. The openings 114 may be formed in a similar manner as those previously described for FIG. 16.

In FIG. 29, upper dielectric structures 110U are formed in the openings 114. The upper dielectric structures 110U may be formed in a similar manner as those previously described for FIG. 18.

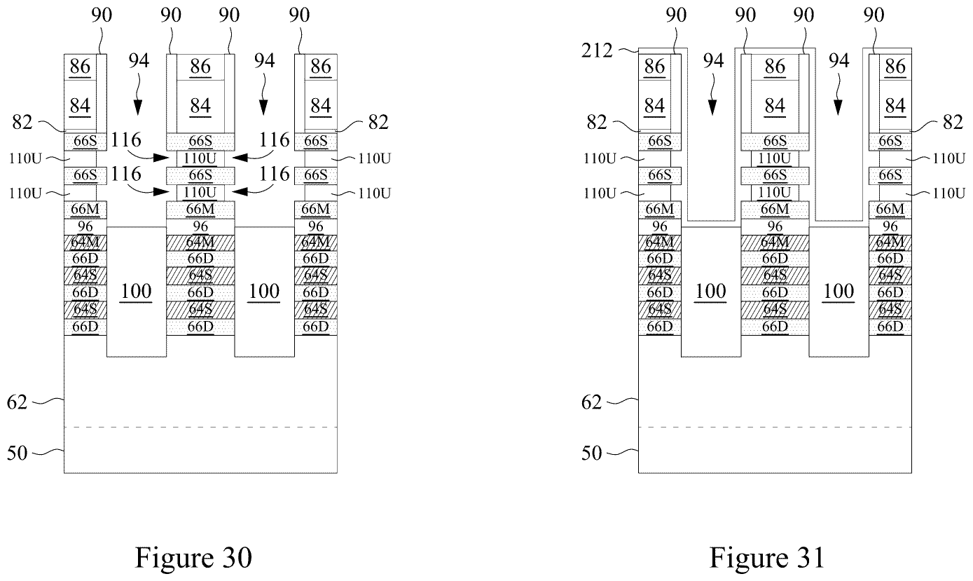

In FIG. 30, portions of the sidewalls of the upper dielectric structures 110U exposed by the source/drain recesses 94 are recessed to form upper sidewall recesses 116U. The sidewalls may be recessed by any acceptable etch process, such as one that is selective to the material of the upper dielectric structures 110U (e.g., selectively etches the material of the upper dielectric structures 110U at a faster rate than the materials of the second nanostructures 66 and the isolation structures 96). The etching may be isotropic. Although sidewalls of the upper dielectric structures 110U are illustrated as being straight after the recessing, the sidewalls may be concave or convex.

In FIG. 31, a dielectric layer 212 is formed in the upper sidewall recesses 116U and the source/drain recesses 94. The dielectric layer 212 may be formed of a suitable insulating material. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material of the dielectric layer 212 has a high etching selectivity to the insulating material of the dielectric structures 110. The insulating material may be formed by a deposition process, such as ALD, CVD, or the like.

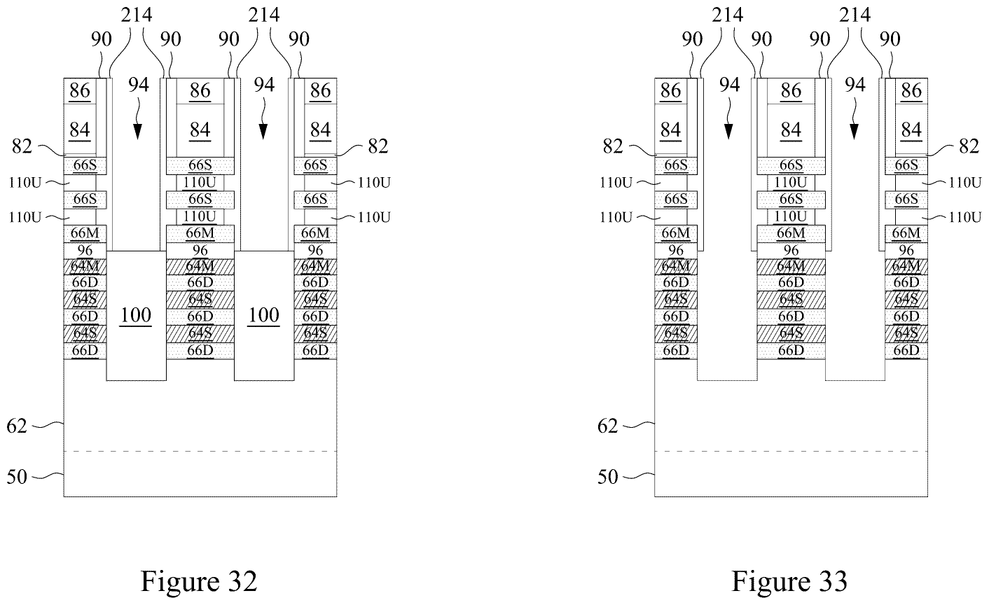

In FIG. 32, the dielectric layer 212 is patterned to form outer spacers 214. The outer spacers 214 are disposed on the sidewalls of the upper dielectric structures 110U, the upper semiconductor nanostructures 66S, the second middle nanostructures 66M, and the gate spacers 90. The outer spacers 214 are disposed in the upper sidewall recesses 116U, and have portions between the second nanostructures 66. Any acceptable etch process, such as a dry etch, may be performed to pattern the dielectric layer 212. The etching may be anisotropic. The etching is selective to the dielectric material of the dielectric layer 212 (e.g., selectively etches the material of the dielectric layer 212 at a faster rate than the material of the sacrificial dielectric 100). In some embodiments, the etching process etches the material of the dielectric layer 212 at least 30 times faster than the material of the sacrificial dielectric 100. Some recessing of the sacrificial dielectric 100 may occur when etching the dielectric layer 212. The dielectric layer 212, when etched, has portions left on the sidewalls of the upper dielectric structures 110U, the upper semiconductor nanostructures 66S, the second middle nanostructures 66M, and the gate spacers 90 (thus forming the outer spacers 214).

In FIG. 33, the sacrificial dielectric 100 is removed from the source/drain recesses 94. The sacrificial dielectric 100 may be removed in a similar manner as that previously described for FIG. 11.

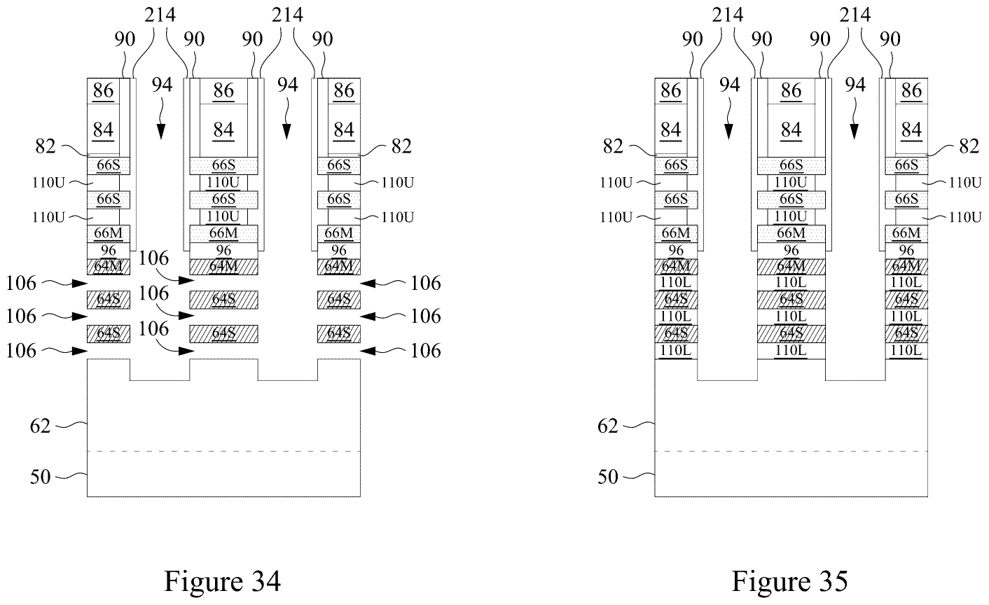

In FIG. 34, the lower dummy nanostructures 66D are removed to form openings 106 between the first nanostructures 64. The openings 106 may be formed in a similar manner as those previously described for FIG. 12.

In FIG. 35, lower dielectric structures 110L are formed in the openings 106. The lower dielectric structures 110L may be formed in a similar manner as those previously described for FIG. 14. The upper dielectric structures 110U and the lower dielectric structures 110L are each formed of the same insulating material. The upper dielectric structures 110U and the lower dielectric structures 110L may further be collectively referred to as the dielectric structures 110.

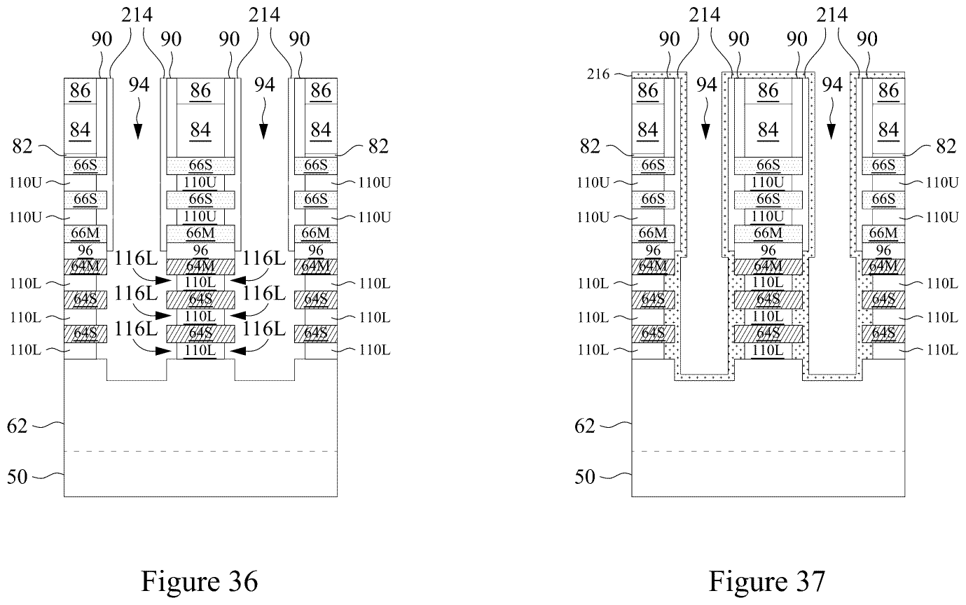

In FIG. 36, portions of the sidewalls of the lower dielectric structures 110L exposed by the source/drain recesses 94 are recessed to form lower sidewall recesses 116L. The sidewalls may be recessed by any acceptable etch process, such as one that is selective to the material of the lower dielectric structures 110L (e.g., selectively etches the material of the lower dielectric structures 110L at a faster rate than the materials of the first nanostructures 64, the isolation structures 96, and the outer spacers 214). The etching may be isotropic. The outer spacers 214 protect the upper dielectric structures 110U and the second nanostructures 66 during the etching. Although sidewalls of the lower dielectric structures 110L are illustrated as being straight after the recessing, the sidewalls may be concave or convex.

In FIG. 37, a dielectric layer 216 is formed in the lower sidewall recesses 116L and the source/drain recesses 94. The dielectric layer 216 may be formed of a suitable insulating material. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material of the dielectric layer 216 has a high etching selectivity to the insulating material of the dielectric structures 110. The insulating material may be formed by a deposition process, such as ALD, CVD, or the like.

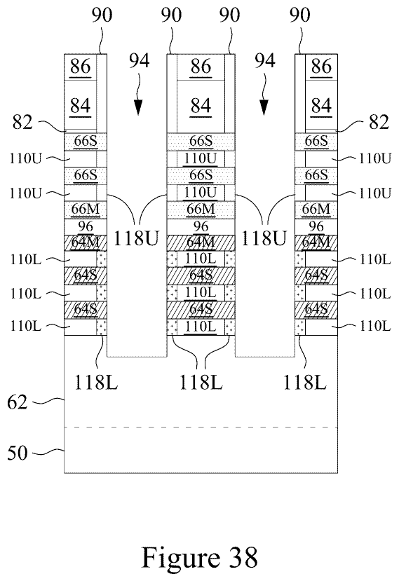

In FIG. 38, the dielectric layer 216 and the outer spacers 214 are etched to form, respectively, lower inner spacers 118L and upper inner spacers 118U. The etching of the dielectric layer 216 and the outer spacers 214 may be anisotropic. For example, the etch process may be a dry etch such as a RIE, a NBE, or the like. The etching is selective to the materials of the dielectric layer 216 and the outer spacers 214 (e.g., selectively etches the materials of the dielectric layer 216 and the outer spacers 214 at a faster rate than the materials of the nanostructures 64, 66 and the isolation structures 96). In some embodiments, the etching process etches the materials of the dielectric layer 216 and the outer spacers 214 at least 50 times faster than the material of the isolation structures 96. The dielectric layer 216, when etched, has portions remaining in the lower sidewall recesses 116L (thus forming the lower inner spacers 118L). The outer spacers 214, when etched, have portions remaining in the upper sidewall recesses 116U (thus forming the upper inner spacers 118U). The upper inner spacers 118U and the lower inner spacers 118L may further be collectively referred to as the inner spacers 118. In some embodiments, the dielectric material of the upper inner spacers 118U is different from the dielectric material of the lower inner spacers 118L. Subsequently additional processing steps as previously described may be performed to complete formation of the CFETs.

In an embodiment, a device includes: first semiconductor nanostructures including a first semiconductor material; second semiconductor nanostructures including a second semiconductor material, the second semiconductor material being different from the first semiconductor material, the second semiconductor nanostructures disposed above the first semiconductor nanostructures; a first gate structure around the first semiconductor nanostructures, the first gate structure including a first work function tuning metal; and a second gate structure around the second semiconductor nanostructures, the second gate structure including a second work function tuning metal, the second work function tuning metal being different from the first work function tuning metal, the second gate structure disposed above the first gate structure. In some embodiments of the device, the first semiconductor material is silicon-germanium, the second semiconductor material is silicon, the first work function tuning metal is a p-type work function tuning metal, and the second work function tuning metal is an n-type work function tuning metal. In some embodiments of the device, the first semiconductor material is silicon, the second semiconductor material is silicon-germanium, the first work function tuning metal is an n-type work function tuning metal, and the second work function tuning metal is a p-type work function tuning metal. In some embodiments, the device further includes: an isolation structure between the first semiconductor nanostructures and the second semiconductor nanostructures. In some embodiments, the device further includes: a first epitaxial source/drain region adjacent the first semiconductor nanostructures; a first inner spacer between the first epitaxial source/drain region and the first gate structure, the first inner spacer including a first dielectric material; a second epitaxial source/drain region adjacent the second semiconductor nanostructures; and a second inner spacer between the second epitaxial source/drain region and the second gate structure, the second inner spacer including a second dielectric material, the second dielectric material different from the first dielectric material. In some embodiments, the device further includes: a first epitaxial source/drain region adjacent the first semiconductor nanostructures; a first inner spacer between the first epitaxial source/drain region and the first gate structure; a second epitaxial source/drain region adjacent the second semiconductor nanostructures; and a second inner spacer between the second epitaxial source/drain region and the second gate structure, the first inner spacer and the second inner spacer including a same dielectric material.

In an embodiment, a device includes: lower semiconductor nanostructures including a first semiconductor material; a lower epitaxial source/drain region adjacent the lower semiconductor nanostructures, the lower epitaxial source/drain region having a first conductivity type; upper semiconductor nanostructures including a second semiconductor material, the second semiconductor material different from the first semiconductor material; and an upper epitaxial source/drain region adjacent the upper semiconductor nanostructures, the upper epitaxial source/drain region having a second conductivity type, the second conductivity type being opposite the first conductivity type. In some embodiments of the device, the first semiconductor material is silicon-germanium, the second semiconductor material is silicon, the lower epitaxial source/drain region is a p-type source/drain region, and the upper epitaxial source/drain region is an n-type source/drain region. In some embodiments of the device, the first semiconductor material is silicon, the second semiconductor material is silicon-germanium, the lower epitaxial source/drain region is an n-type source/drain region, and the upper epitaxial source/drain region is a p-type source/drain region. In some embodiments, the device further includes: an isolation structure between the lower semiconductor nanostructures and the upper semiconductor nanostructures; and an inter-layer dielectric between the lower epitaxial source/drain region and the upper epitaxial source/drain region.

In an embodiment, a method includes: forming lower semiconductor nanostructures, lower dummy nanostructures, upper semiconductor nanostructures, and upper dummy nanostructures, the lower semiconductor nanostructures and the upper dummy nanostructures formed of a first semiconductor material, the upper semiconductor nanostructures and the lower dummy nanostructures formed of a second semiconductor material; replacing the lower dummy nanostructures with lower dielectric structures, the lower dielectric structures formed of a first dielectric material; replacing the upper dummy nanostructures with upper dielectric structures, the upper dielectric structures formed of the first dielectric material; and removing the lower dielectric structures and the upper dielectric structures with an etching process that selectively etches the first dielectric material at a faster rate than the first semiconductor material and the second semiconductor material. In some embodiments of the method, removing the lower dielectric structures forms lower openings between the lower semiconductor nanostructures, removing the upper dielectric structures forms upper openings between the upper semiconductor nanostructures, and the method further includes: forming a lower gate structure in the lower openings between the lower semiconductor nanostructures; and forming an upper gate structure in the upper openings between the upper semiconductor nanostructures. In some embodiments of the method, the first semiconductor material is silicon-germanium and the second semiconductor material is silicon. In some embodiments of the method, the first semiconductor material is silicon and the second semiconductor material is silicon-germanium. In some embodiments of the method, the lower dummy nanostructures are replaced before the upper dummy nanostructures are replaced. In some embodiments of the method, the lower dummy nanostructures are replaced after the upper dummy nanostructures are replaced. In some embodiments, the method further includes: forming inner spacers adjacent the lower dielectric structures and the upper dielectric structures, the inner spacers formed of a second dielectric material. In some embodiments of the method, the first dielectric material is silicon nitride, the second dielectric material is silicon oxycarbonitride, and the etching process includes a wet etch with phosphoric acid. In some embodiments of the method, the first dielectric material is silicon oxide, the second dielectric material is silicon oxycarbonitride, and the etching process includes a wet etch with dilute hydrofluoric acid. In some embodiments of the method, the first dielectric material is aluminum oxide, the second dielectric material is silicon oxycarbonitride, and the etching process includes a wet etch with phosphoric acid and a sulfuric peroxide mixture.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
first semiconductor nanostructures comprising a first semiconductor material having a first band gap;
a first source/drain region adjacent the first semiconductor nanostructures;
second semiconductor nanostructures comprising a second semiconductor material having a second band gap, the second band gap different from the first band gap; and
a second source/drain region adjacent the second semiconductor nanostructures, wherein a first line extending through the first source/drain region and the second source/drain region is parallel to a second line extending through each of the first semiconductor nanostructures and each of the second semiconductor nanostructures, and wherein the first semiconductor nanostructures and the second semiconductor nanostructures extend lengthwise in a direction that is perpendicular to the first line and the second line.

2. The device of claim 1, wherein the first band gap is less than the second band gap, the first source/drain region exerts a compressive strain on the first semiconductor nanostructures, and the second source/drain region exerts a tensile strain on the second semiconductor nanostructures.

3. The device of claim 1, wherein the first band gap is greater than the second band gap, the first source/drain region exerts a tensile strain on the first semiconductor nanostructures, and the second source/drain region exerts a compressive strain on the second semiconductor nanostructures.

4. The device of claim 1, further comprising:
an isolation structure between the first semiconductor nanostructures and the second semiconductor nanostructures; and
an inter-layer dielectric between the first source/drain region and the second source/drain region.

5. The device of claim 1, further comprising:
a first gate structure around the first semiconductor nanostructures;
a first spacer between the first gate structure and the first source/drain region, the first spacer comprising a first dielectric material;
a second gate structure around the second semiconductor nanostructures; and
a second spacer between the second gate structure and the second source/drain region, the second spacer comprising a second dielectric material, the second dielectric material different from the first dielectric material.

6. The device of claim 1, further comprising:
a first gate structure around the first semiconductor nanostructures;
a first spacer between the first gate structure and the first source/drain region;
a second gate structure around the second semiconductor nanostructures; and
a second spacer between the second gate structure and the second source/drain region, the first spacer and the second spacer comprising a same dielectric material.

7. The device of claim 1, further comprising:
a gate dielectric layer around the first semiconductor nanostructures and around the second semiconductor nanostructures;
a first gate electrode over the gate dielectric layer and around the first semiconductor nanostructures, the first gate electrode comprising a first work function tuning metal; and
a second gate electrode over the gate dielectric layer and around the second semiconductor nanostructures, the second gate electrode comprising a second work function tuning metal that is different from the first work function tuning metal.

8. The device of claim 1, further comprising source/drain contacts electrically coupled to the first source/drain region and the second source/drain region.

9. The device of claim 1, wherein the first line and the second line each extend through a substrate.

10. A device comprising:
a first source/drain region;
a first channel region adjacent to the first source/drain region;
a first gate structure around the first channel region;
a first spacer between the first gate structure and the first source/drain region, the first spacer comprising a first dielectric material;
a second source/drain region disposed above the first source/drain region;
a second channel region adjacent to the second source/drain region, the second channel region disposed above the first channel region;
a second gate structure around the second channel region, the second gate structure disposed above the first gate structure; and
a second spacer between the second gate structure and the second source/drain region, the second spacer comprising a second dielectric material, the second dielectric material different from the first dielectric material.

11. The device of claim 10, wherein the first channel region has a greater hole mobility than the second channel region, and the second channel region has a greater electron mobility than the first channel region.

12. The device of claim 10, wherein the first channel region has a greater electron mobility than the second channel region, and the second channel region has a greater hole mobility than the first channel region.

13. The device of claim 10, wherein the first channel region comprises a plurality of first semiconductor nanostructures, the second channel region comprises a plurality of second semiconductor nanostructures, the first semiconductor nanostructures comprise a first semiconductor material, the second semiconductor nanostructures comprise a second semiconductor material, and the second semiconductor material is different from the first semiconductor material.

14. The device of claim 10, further comprising:
an isolation structure between the first channel region and the second channel region; and
an inter-layer dielectric between the first source/drain region and the second source/drain region.

15. A device comprising:
a lower transistor comprising:
lower semiconductor nanostructures comprising a first semiconductor material; and
a lower source/drain region adjacent to the lower semiconductor nanostructures; and
an upper transistor that has a different threshold voltage than the lower transistor, the upper transistor comprising:
upper semiconductor nanostructures stacked vertically above the lower semiconductor nanostructures, the upper semiconductor nanostructures comprising a second semiconductor material, the second semiconductor material different from the first semiconductor material; and
an upper source/drain region adjacent to the upper semiconductor nanostructures.

16. The device of claim 15, wherein the lower transistor further comprises a lower gate structure around the lower semiconductor nanostructures, the upper transistor further comprises an upper gate structure around the upper semiconductor nanostructures, and the upper gate structure has a different work function than the lower gate structure.

17. The device of claim 15, wherein the first semiconductor material is silicon and the second semiconductor material is silicon-germanium, the lower source/drain region comprises n-type majority carriers, and the upper source/drain region comprises p-type majority carriers.

18. The device of claim 15, wherein the first semiconductor material is silicon-germanium and the second semiconductor material is silicon, the lower source/drain region comprises p-type majority carriers, and the upper source/drain region comprises n-type majority carriers.

19. The device of claim 15, further comprising:
an isolation structure between the lower semiconductor nanostructures and the upper semiconductor nanostructures; and
an inter-layer dielectric between the lower source/drain region and the upper source/drain region, the isolation structure adjacent to the inter-layer dielectric.

20. The device of claim 15, further comprising a substrate, wherein the lower transistor is disposed between the substrate and the upper transistor.
